(19) United States
(12) Patent Application Publication
(10) Pub. No.: US 2015/0193301 A1
(43) Pub. Date: Jul. 9, 2015

(54) MEMORY CONTROLLER AND MEMORY SYSTEM

(71) Applicant: Kabushiki Kaisha Toshiba, Minato-ku (JP)

(72) Inventors: Hiroshi Sukegawa, Tokyo (JP); Naomi Takeda, Yokohama (JP); Hiroshi Yao, Yokohama (JP)

(73) Assignee: Kabushiki Kaisha Toshiba, Minato-ku (JP)

(21) Appl. No.: 14/469,754

(22) Filed: Aug. 27, 2014

Related U.S. Application Data
(60) Provisional application No. 61/923,916, filed on Jan. 6, 2014.

(51) Int. Cl. G06F 11/10; G11C 29/08; G06F 12/02

(52) U.S. Cl. CPC G06F 11/1072; G06F 12/0246; G11C 29/08; G06F 2212/7205

(57) ABSTRACT

A controller according to one embodiment controls a memory, the memory including blocks and configured to erase data in the blocks with each of the blocks as a minimum unit. Each of the blocks includes unit memory areas each specified by an address. The controller is configured to add a code for error correction to received data to generate a data unit, divide the data unit into data unit sections, and write the data unit sections in unit memory areas of respective blocks, the unit memory areas having different addresses.

This application claims the benefit of U.S. Provisional Application No. 61/923,916, filed Jan. 6, 2014, the entire contents of which are incorporated herein by reference.

### FIELD

Embodiments relate to a memory controller and a memory system.

### BACKGROUND

NAND flash memories with a three-dimensional structure are known.

### BRIEF DESCRIPTION OF THE DRAWINGS

FIG. 1 illustrates functional blocks of a memory device according to a first embodiment;

FIG. 2 illustrates functional blocks of a memory according to the first embodiment;

FIG. 3 illustrates a perspective view of a part of a memory cell array according to the first embodiment;

FIG. 4 illustrates circuits of a part of the memory cell array according to the first embodiment;

FIG. 5 illustrates possible writes in the memory of FIGS. 3 and 4;

FIG. 6 illustrates writes according to the first embodiment;

FIG. 7 illustrates a state in a process before FIG. 6;

FIG. 8 illustrates a state following FIG. 7;

FIG. 9 illustrates a state during writes of the second embodiment;

FIG. 10 illustrates a state following FIG. 9;

FIG. 11 illustrates a state following FIG. 10;

FIG. 12 illustrates a state following FIG. 11;

FIGS. 13A and 13B illustrate a state following FIG. 12;

FIGS. 14A and 14B illustrate a state following FIGS. 13A and 13B;

FIGS. 15A and 15B illustrate a state following FIGS. 14A and 14B;

FIGS. 16A and 16B illustrate a state in an example of garbage collection of a third embodiment;

FIGS. 17A and 17B illustrate a state following FIGS. 16A and 16B;

FIGS. 18A and 18B illustrate a state following FIGS. 17A and 17B;

FIGS. 19A and 19B illustrate a state following FIGS. 18A and 18B;

FIGS. 20A and 20B illustrate a state following FIGS. 19A and 19B;

FIGS. 21A and 21B, and 21C illustrate a state in another example of garbage collection of the third embodiment;

FIGS. 22A and 22B, and 22C illustrate a state following FIGS. 21A, 21B, and 21C.

FIGS. 23A and 23B, and 23C illustrate a state following FIGS. 22A, 22B, and 22C;

FIGS. 24A, 24B, and 24C illustrate a state following FIGS. 23A, 23B, and 23C;

FIGS. 25A, 25B, and 25C illustrate a state following FIGS. 24A, 24B, and 24C;

FIGS. 26A and 26B illustrate a state following FIGS. 25A, 25B, and 25C; and

FIGS. 27A and 27B illustrate a state following FIGS. 26A and 26B.

### DETAILED DESCRIPTION

A controller according to one embodiment controls a memory, the memory comprising blocks and configured to erase data in the blocks with each of the blocks as a minimum unit. Each of the blocks comprises unit memory areas each specified by an address. The controller is configured to add a code for error correction to received data to generate a data unit, divide the data unit into data unit sections, and write the data unit sections in unit memory areas of respective blocks, the unit memory areas having different addresses.

Embodiments will now be described with reference to the figures. Components with substantially the same functionality and configuration will be referred to with the same reference number and duplicate descriptions will be made only when required. The figures are schematic. Each embodiment illustrates devices and methods for embodying technical ideas of that embodiment, which does not limit the quality, shape, structure, arrangement, etc., of the material of a component to the following examples. Moreover, descriptions for a particular embodiment also apply to other embodiments, unless it is explicitly or obviously rejected.

### First Embodiment

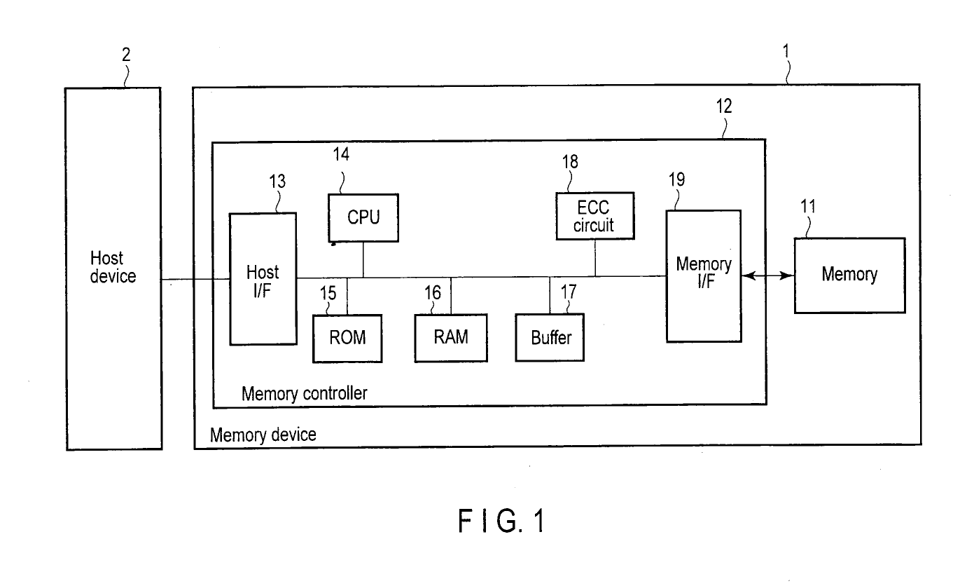

FIG. 1 illustrates functional blocks of a memory device according to the first embodiment. The memory device 1 includes a semiconductor memory 11 and a memory controller 12. The memory device 1 is an SD card, for example. The memory device 1 communicates with a host device 2.

Each functional block can be implemented as hardware, computer software, or a combination of the both. For this reason, in order to clearly illustrate this interchangeability of hardware and software, descriptions will be made in terms of their functionality in general. Moreover, it is not essential that each functional block be distinguished as per the following examples. For example, some of the functions may be implemented by functional blocks different from those illustrated below. Furthermore, an illustrated functional block may be divided into functional sub-blocks.

The memory controller 12 receives, for example, write commands and read commands from the host device 2, and accesses the memory 2 in accordance with the commands. The memory controller 12 includes a host interface (I/F) 13, a central processing unit (CPU) 14, a read only memory (ROM) 15, a random access memory (RAM) 16, a buffer 17, an error correction code circuit (ECC circuit) 17 and a memory interface 19. They are coupled by a bus.

The host interface 13 allows the memory device 1 to be interfaced with the host device 2. The CPU 14 manages the operation of the whole memory device 1 in accordance with control programs. The ROM 15 stores firmware, such as control programs used by the CPU 14. The RAM 16 is used as a work area for the CPU 14, and stores, for example, control programs and various kinds of tables. The buffer 17 temporarily stores data.

The ECC circuit 18 includes an ECC encoder and an ECC decoder. The ECC encoder generates parities (error correction codes) from received data (ECC encoder input) in accordance with predetermined rules for producing error correction codes to output a set of an ECC encoder input and an error correction code (ECC encoder output). The ECC decoder corrects an error or errors of data in accordance with received data and its parities.

The memory interface 19 allows the memory controller 12 to be interfaced with the memory 11.

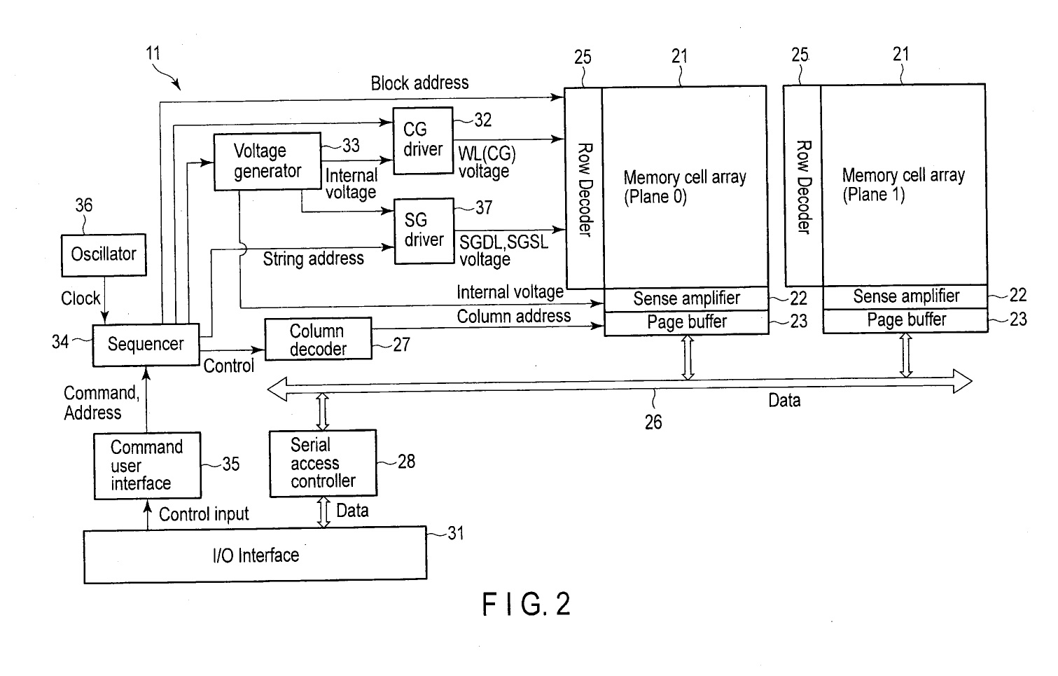

FIG. 2 illustrates functional blocks of the memory 11 according to the first embodiment. As shown in FIG. 2, the memory 11 includes components such as memory cell arrays 21, sense amplifiers 22, page buffers 23, a row decoder 25, a data bus 26, a column decoder 27, a serial access controller 28, an I/O interface 31, a CG driver 32, a voltage generator 33, a sequencer (or controller) 34, a command user interface 35, an oscillator 36 and SG drivers 37. The memory 11 corresponds to one semiconductor chip, for example.

The memory 11 includes multiple memory cell arrays 21. FIG. 1 illustrates two memory cell arrays 21; however the memory 11 may include three or more memory cell arrays 21. Each memory cell array 21 includes memory blocks, which may be simply referred to as blocks hereinafter. Each block has strings. Each string includes serially-coupled memory cell transistors and two select gate transistors at both ends thereof. Multiple strings are coupled to a bit line. Specific multiple memory cell transistors share a word line. Memory cell transistors which share a word line configure a physical unit. The memory space of one physical unit configures one or more pages. Data is read per page and erased per block. When the memory 11 is configured to store data of two or more bits per memory cell, two or more pages are assigned to the memory space of one physical unit. In this case, a write may be executed per page in one physical unit, or together in some or all pages in one physical unit. In order to encompass any scenario, the following description will be made with a physical unit used as a write unit. The memory cell array 21 has a three-dimensional structure, which will be described later in detail.

A set of the sense amplifier 22, page buffer 23, and row decoder 25 is provided for each memory cell array 21. Each sense amplifier 22 includes sense amplifier units coupled to respective bit lines, and senses and amplifies the potential on the bit lines. Each page buffer 23 receives a column address, reads data from the specified memory cell transistors in accordance with the column address, temporarily stores the read data, and outputs it to the data bus 26, during a read. Each page buffer 23 receives data from outside the memory 11 through the data bus 26 in accordance with the column address and temporarily stores the received data during a write. The column address is supplied by the column decoder 27.

The data bus 26 is coupled to the serial access controller 28. The serial access controller 28 is coupled to the I/O interface 31. The I/O interface 31 includes signal terminals, communicates with the memory interface 19 of the memory controller 12, and allows the memory 11 to be interfaced with the memory controller 12. The serial access controller 28 performs control including translation between a parallel signal on the data bus 26 and a serial signal flowing through the I/O interface 31.

Each row decoder 25 receives a block address from the sequencer 34 and selects a block in accordance with the received block address. Specifically, each row decoder 25 is coupled to the CG driver 32, and couples outputs of the CG driver 32 to a selected block. The CG driver 32 receives voltages from the voltage generator 33, and, in accordance with control by the sequencer 34, generates voltages required for various operations of the memory 11 such as a read, write, and erase. The CG driver 32 is shared by the planes. The voltages output from the CG driver 32 are applied to the word lines.

An SG driver 37 is provided for each plane. Each SG driver 37 receives a string address from the sequencer 34, and selects a string in accordance with the received string address. Specifically, each SG driver 37 receives voltages from the voltage generator 33, and outputs the voltages only for a selected string. The voltages output from the SG driver 37 are applied to select gate lines (or gate electrodes of select gate transistors).

The voltage generator 33 also provides the sense amplifier 22 with voltages required for its operation. The sequencer 34 receives signals, such as a command and an address, from the command user interface 35, and operates in accordance with a clock from the oscillator 36. The sequencer 34 controls various components (functional blocks) in the memory 11 in accordance with the received signal. For example, the sequencer 34 controls the column decoder 27, CG driver 32, voltage generator 33 and SG drivers 37 in accordance with the received signals, such as the command and address. Moreover, the sequencer 34 outputs the aforementioned block address and string address in accordance with the received signals, such as the command and address. The command user interface 35 receives a control signal via the I/O interface 31. The command user interface 35 decodes the received control signal, and obtains commands and addresses, and the like.

The memory 11 may be configured to store data of two or more bits in one memory cell.

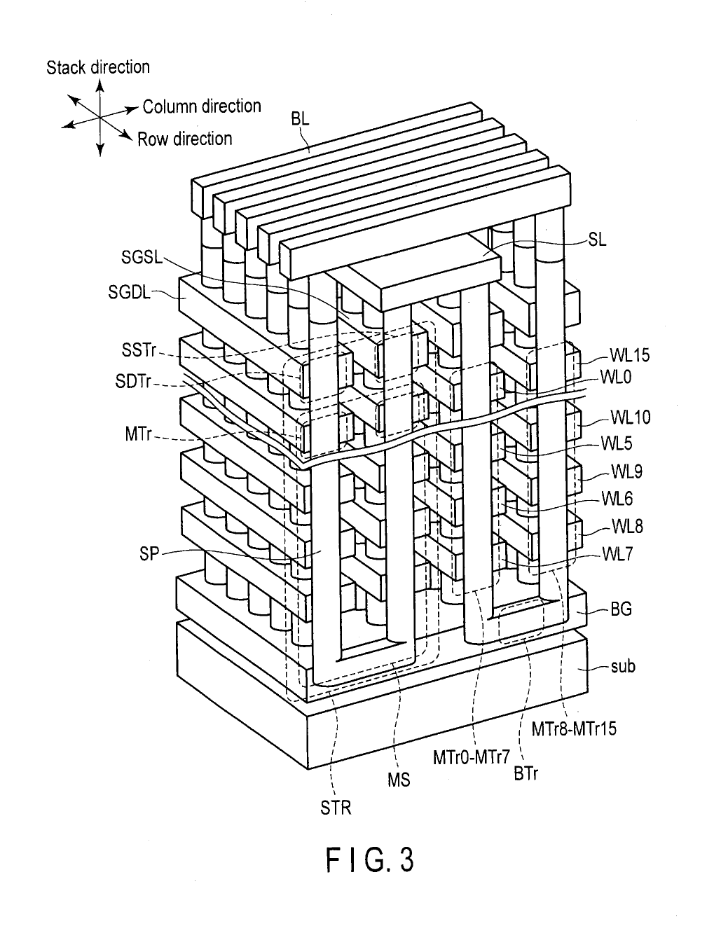

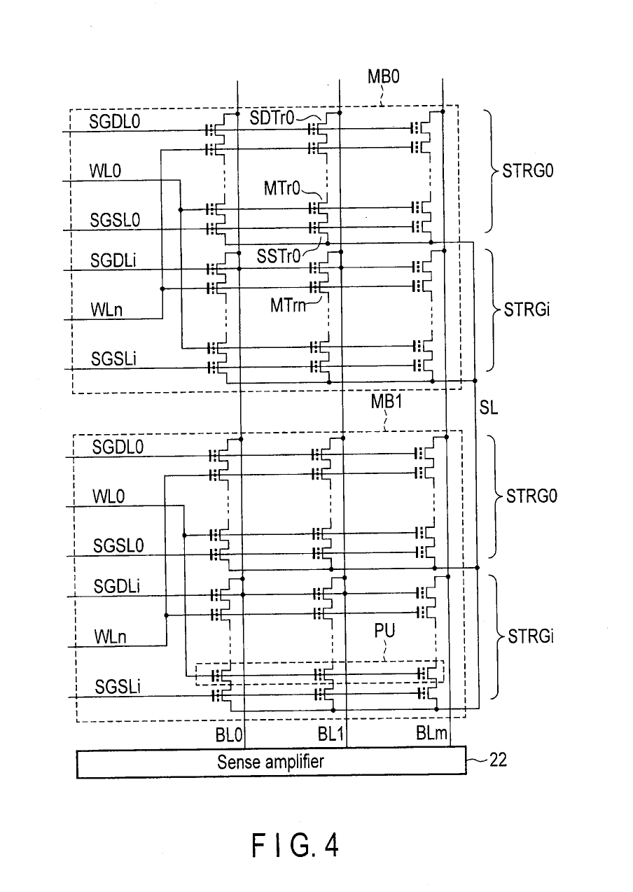

The memory cell array 21 has the components and connections illustrated in FIGS. 3 and 4. FIG. 3 is a perspective view of the memory cell array according to the first embodiment. FIG. 4 is a circuit diagram of a part (i.e., two physical blocks MB) of the memory cell array according to the first embodiment. As illustrated in FIGS. 3 and 4, the memory cell array 21 has bit lines BL, source (cell source) lines SL, and physical blocks MB. The source lines SL extend along the row direction. The bit lines BL extend along the column direction. The row and column directions cross each other at right angles. The physical blocks MB are in a line along the column direction at predetermined intervals. In each physical block MB, i+1 (i being 11, for example) strings STR are coupled to one bit line BL.

A string STR has a memory string MS, a source-side select gate transistor SSTr, and a drain-side select gate transistor SDTr. Memory strings MS are located above a substrate sub along the stack direction. A memory string MS includes n+1 memory cell transistors (an example of n=15 is illustrated and described) MTr0 to MTr15 and a back gate transistor BTr which are serially coupled. When reference numerals with a subscript (for example, cell transistors Mtr) do not need to be distinguished from each other, a reference numeral without the subscript is used, and this refers to all reference numerals with subscripts. The cell transistors MTr0 to MTr7 are located in the described order toward the substrate sub along the stack direction. The cell transistors MTr8 to MTr15 are located in the described order away from the substrate sub along the stack direction. The cell transistors MTr include a semiconductor pillar SP, an insulator on the surface of the semiconductor pillar SP, and respective word lines (or control gates) WL as will be described in detail later. A back gate transistor BTr is coupled between bottom cell transistors MTr7 and MTr8.

The select gate transistors SSTr and SDTr are located above top cell transistors MTr0 and MTr15 along the stack direction, respectively. The drain of a transistor SSTr is coupled to a source of a cell transistor MTr0. The source of a transistor SDTr is coupled to a drain of a cell transistor MTr15. The source of a transistor SSTr is coupled to the source line SL. The drain of a transistor SDTr is coupled to a bit line BL.

Strings located in a line along the row direction configure a string group STRG. For example, all strings located in a line along the row direction and respectively coupled to all bit lines BL configure a string group STRG. In each string group STRG, the strings have their respective gates of the cell transistors MTr0 commonly coupled to the word line WL0. Similarly, in each string group STRG, the strings have their respective gates of cell transistors MtrX commonly coupled to a word line WLX. The word lines WL extend along the row direction. Respective gates of the back gate transistors BTr are commonly coupled to a back gate line BG.

In each string group STRG, the strings STR have their respective gates of the transistors SDTr commonly coupled to a drain-side select gate line SGDL. In each string group STRG, the strings STR have their respective drains of the respective transistors SDTr coupled to respective bit lines BL. The select gate lines SGDL extend along the row direction. The string groups STRG0 to STRGi are provided with select gate lines SGDL0 to SGDLi, respectively.

In each string group STRG, the strings STR have their respective gates of the transistors SSTr commonly coupled to a source-side select gate line SGSL. Respective sources of transistors SSTr from two strings STR located in a line along the column direction are coupled to the same source line SL. In each string group STRG, the strings STR have their respective sources of the transistors SSTr coupled to the same source lines SL. The select gate lines SGSL and source line SL extend along the row direction. The string groups STRG0 to STRGi are provided with select gate lines SGSL0 to SGSLi, respectively.

Cell transistors of strings which are in one string group STRG and coupled to the same word line WL configure a physical unit PU.

In each block MB, the word lines of the same number from different strings are coupled to each other. Specifically, word lines WL0 of all strings in one block MB are coupled to each other, and word lines WLX are coupled to each other, for example.

For access to a cell transistor MTr, one block MB is selected and one string group STRG is selected. For selecting one block, a signal to select a block MB is output to only a block MB specified by a block address signal. With such a block select signal, in the selected block MB, the word lines WL and select gate lines SGSL and SGDL are coupled to drivers.

Furthermore, for selecting one string group STRG, select transistors SSTr and SDTr only in a selected string group STRG receive voltages for the purpose of selection. In unselected string groups STRG, select-transistors SSTr and SDTr receive voltages for the purpose of non-selection. The voltages for selection depend on operations such as read and write. The voltages for non-selection also depend on operations such as read and write.

During writes by the memory device 1, the memory controller 12 writes an ECC encoder output which has been output from the ECC encoder in the ECC circuit 18 into a particular set of physical units. A single ECC encoder output is referred to as a data unit in this specification and the claims. Specifically, a single data unit is the minimum data required to correct one or more errors in that data unit, and the whole of that data unit is necessary to correct errors in that data unit.

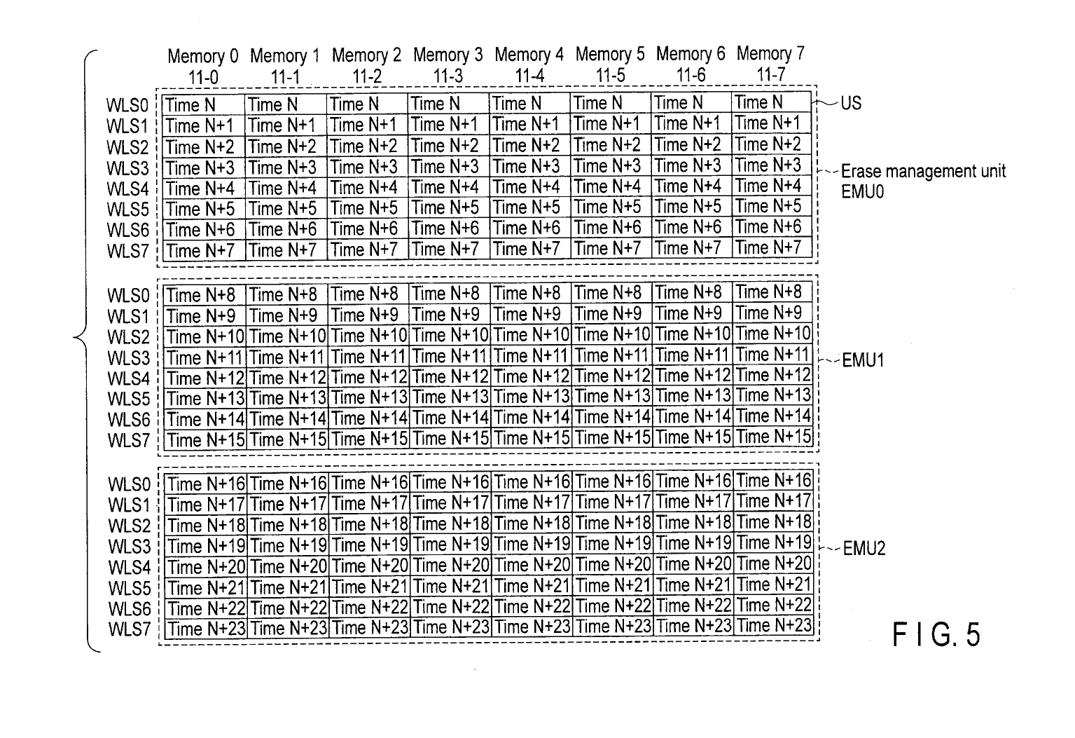

In the memory device 1 including the semiconductor memory 11 with the components and connections of FIGS. 3 and 4, it is conceivable that the memory controller 12 writes data units in accordance with the following rules as the simplest method. FIG. 5 illustrates an example of writes. FIG. 5 relates to an example of the memory device 1 with eight semiconductor memories (or, chips) 11-0 to 11-7 therein. In FIG. 5, each square represents a memory area (or, memory space) by a set of physical units of memory cells coupled to word lines in one or more sets of adjacent word lines (or, word line sets) in a single semiconductor memory 11. The memory area represented by each square is referred to as a unit memory area US herein. Unit memory areas US lining up horizontally are configured by physical units of respective word lines WL of the same addresses, and therefore of respective word lines at the same layers. In each semiconductor memory 11, a set of eight unit memory areas US lining up vertically in FIG. 5 is a minimum set for a data erase. In the memory device 1, generally, for the semiconductor memories 11 to be controlled in parallel, the same word line address is specified in the semiconductor memories 11, which operate in parallel, and different addresses are not specified in different semiconductor memories 11. Therefore, a set of data erase units lining up horizontally in FIG. 5 from all the semiconductor memories 11 corresponds to a data erase unit used when the memory controller 12 controls the semiconductor memories 11 in parallel, as illustrated in FIG. 5. This set of data erase units each from one of all the semiconductor memories 11 controlled in parallel is referred to as an erase management unit in this specification and the claims.

In the memory device 1 under such conditions, the memory controller 12 writes a single data unit in unit memory areas US of a common set of word lines of the semiconductor memories 11-0 to 11-8 in the erase management unit EMU0. Specifically, for example, at a time N, the memory controller 12 writes a particular data unit in a set of physical units by memory cells coupled to a word-line set WLS0 (or, a set of physical units of the word line set WLS0) of each semiconductor memory 11 in the erase management unit EMU0 of FIG. 5. In FIG. 5, the data-unit written at the time N is represented as written in the set of unit memory areas US with “Time N” therein.

Similarly, the memory controller 12 writes the following data unit in a set of physical units of a word line set WLS1 from each semiconductor memory 11 in the erase management unit EMU0 at a time N+1. Specifically, the memory controller 12 writes a data unit in a set of unit memory areas lining up horizontally over the semiconductor memories 11-0 to 11-7 in FIG. 5. Similarly, the memory controller 12 writes a data unit in unit memory areas in a single row in parallel, and executes such writes from the top toward the bottom in FIG. 5 with time.

In such writes, garbage collection is executed as follows. The term garbage collection generally refers to releasing an area including invalid data (or, data items) in a memory device, and involves copying valid data items in a particular erase unit to another place in such a memory with a predetermined erase unit as the memory 11. The area having copied data items before copying is treated as storing invalid data items after the garbage collection (after the copy). Data items in the erase unit which have come to store only invalid data items by the garbage collection are erased thereafter. When, for example, the rate of invalid data items occupying a particular erase unit reaches a predefined value, the garbage collection is executed to that erasure unit. In the FIG. 5 example, when all the data items in a single erase management unit become invalid, all the data items in that erase management unit are erased.

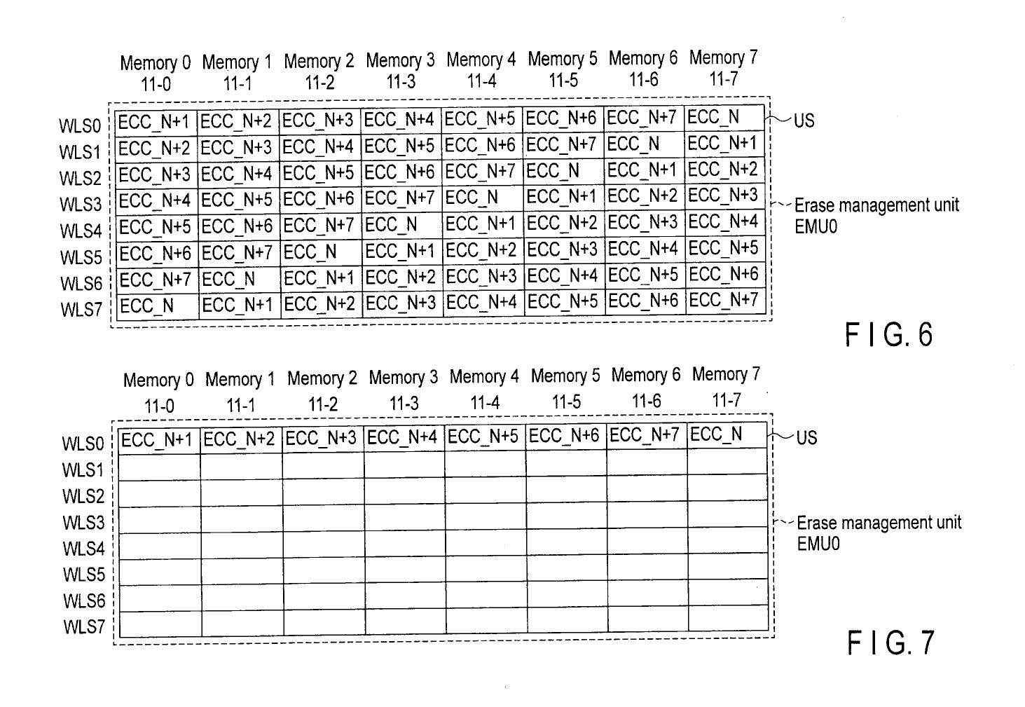

The data writes described above lead to the occurrence of the following phenomena. Generally, different cell transistors in a semiconductor memory have different reliabilities due to, for example, variation in manufacturing processes. Especially, memories with a three-dimensional structure, as in the semiconductor memory 11, vary widely in reliability. This is because the semiconductor pillars SP are formed by burying conductive materials in memory holes which extend through the word lines WL and interlayer dielectrics, and the memory holes have different cross-sectional areas at different depths and in turn have different cross-sectional areas of semiconductor pillars SP with the current techniques. For this reason, cell transistors MTr at different layers have different reliabilities, and the differences in the reliability are significant in the memories of the three-dimensional structure. This results in unit memory areas US of a word line set at an unreliable layer having errors of the data unit corrected with data stored in unreliable unit memory areas US as in FIG. 5. This leads to a low ability to correct errors in data units in such low-reliability unit memory areas US. In light of such phenomena, the memory device 1 according to the first embodiment is configured to operate as described below with reference to FIGS. 6 to 8.

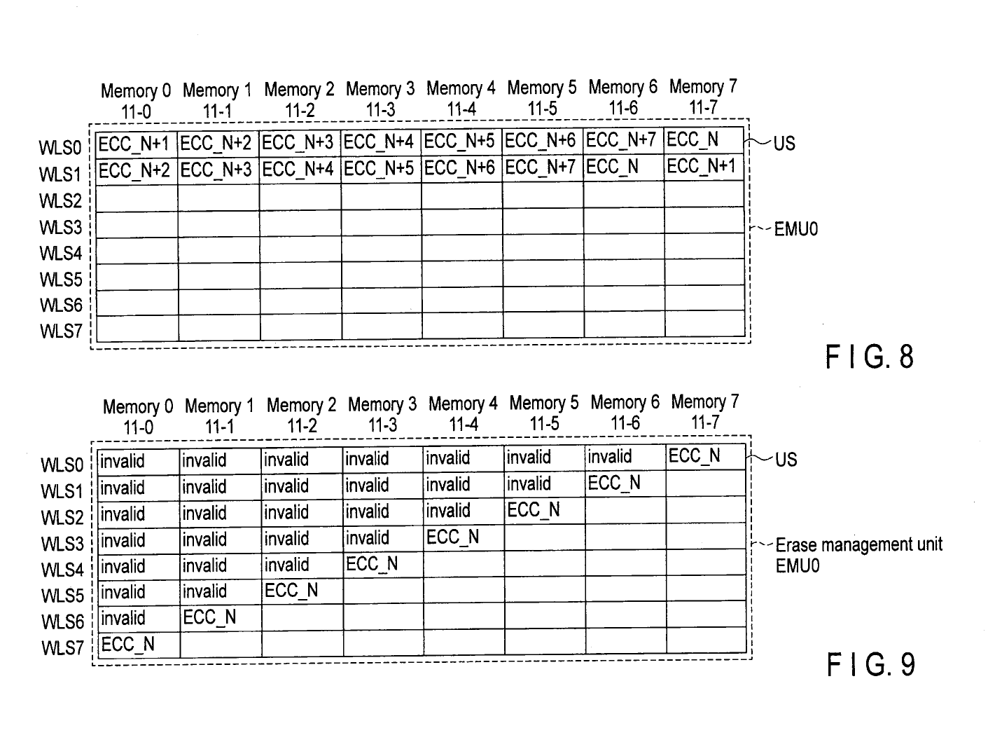

FIG. 6 illustrates the writes of the first embodiment, or areas where data will be written. FIGS. 7 and 8 each illustrate a state in the process to FIG. 6 along time. In FIGS. 6 to 8, each square represents a single unit memory area US as in FIG. 5. In this example, the zeroth to the seventh word line sets WLS0 to WLS7 are defined. Unit memory areas US lining up are also configured by physical units of respective word lines WL of the same address, and therefore of respective word lines at the same layer. Moreover, a set of eight unit memory areas US lining up vertically in FIG. 5 is also a minimum set for a data erase. The memory controller 12 treats a set of erase units of respective semiconductor memories 11-0 to 11-7 as a single unit on operation, and is referred to as an erase management unit herein.

The memory controller 12 is configured to operate as described below with reference to FIGS. 6 to 8. As illustrated in FIG. 6, the memory controller 12 instructs the memories 11 to write a single data unit so that each data unit is written in the below-mentioned areas of the memories 11. A whole data unit is divided into multiple sections (or, data unit sections). Specifically, the memory controller 12 divides a whole data unit ECC_N into separate sections, and stores them in multiple unit memory areas US with a notation of ECC_N therein in a single erase management unit EMU. The sections of the data unit ECC_N are stored in unit memory areas US of word line sets WLS of different addresses in different semiconductor memories 11. More specifically, the memory controller 12 stores the sections of the data unit ECC_N in the semiconductor memories 11-0, 11-1, 11-2, 11-3, 11-4, 11-5, 11-6, and 11-7 in, for example, unit memory areas US of word line sets WLS7, WLS6, WLS5, WLS4, WLS3, WLS2, WLS1, and WLS0, respectively. The sections of a data unit ECC stored respectively in the semiconductor memories 11-0, 11-1, 11-2, 11-3, 11-4, 11-5, 11-6, and 11-7 will be referred to as the zeroth to seventh sections, respectively.

Similarly, the memory controller 12 stores the zeroth to seventh sections of data unit ECC_N+1 in the semiconductor memories 11-0, 11-1, 11-2, 11-3, 11-4, 11-5, 11-6, and 11-7 in, for example, memory-areas US of the word line sets WLS0, WLS7, WLS6, WLS5, WLS4, WLS3, WLS2, and WLS1, respectively.

The memory controller 12 stores the zeroth to seventh sections of data unit ECC_N+2 in the semiconductor memories 11-0, 11-1, 11-2, 11-3, 11-4, 11-5, 11-6, and 11-7 in, for example, memory-areas US of the word line sets WLS1, WLS0, WLS7, WLS6, WLS5, WLS4, WLS3, and WLS2, respectively.

The memory controller 12 stores the zeroth to seventh sections of data unit ECC_N+3 in the semiconductor memories 11-0, 11-1, 11-2, 11-3, 11-4, 11-5, 11-6, and 11-7 in, for example, memory-areas US of the word line sets WLS2, WLS1, WLS0, WLS7, WLS6, WLS5, WLS4, and WLS3, respectively.

The memory controller 12 stores the zeroth to seventh sections of data unit ECC_N+4 in the semiconductor memories 11-0, 11-1, 11-2, 11-3, 11-4, 11-5, 11-6, and 11-7 in, for example, memory-areas US of the word line sets WLS3, WLS2, WLS1, WLS0, WLS7, WLS6, WLS5, and WLS4, respectively.

The memory controller 12 stores the zeroth to seventh sections of data unit ECC_N+5 in the semiconductor memories 11-0, 11-1, 11-2, 11-3, 11-4, 11-5, 11-6, and 11-7 in, for example, memory-areas US of the word line sets WLS4, WLS3, WLS2, WLS1, WLS0, WLS7, WLS6, and WLS5, respectively.

The memory controller 12 stores the zeroth to seventh sections of data unit ECC_N+6 in the semiconductor memories 11-0, 11-1, 11-2, 11-3, 11-4, 11-5, 11-6, and 11-7 in, for example, memory-areas US of the word line sets WLS5, WLS4, WLS3, WLS2, WLS1, WLS0, WLS7, and WLS6, respectively.

The memory controller 12 stores the zeroth to seventh sections of data unit ECC_N+7 in the semiconductor memories 11-0, 11-1, 11-2, 11-3, 11-4, 11-5, 11-6, and 11-7 in, for example, memory-areas US of the word line sets WLS6, WLS5, WLS4, WLS3, WLS2, WLS1, WLS0, and WLS7, respectively.

The memory controller 12 executes writes, in parallel to the semiconductor memories 11-0 to 11-7, to unit memory areas US of the same word line set on a word line set basis and executes writes in units of word line sets WLS. Specifically, it executes writes in units of horizontally-lining-up eight unit memory areas US of FIG. 6 sequentially, for example, from the top toward the bottom. To this end, the memory controller 12 uses the ECC circuit 18 to generate data units while holding them in the RAM 16. Specifically, the memory controller 12 receives write data items (or, user data items) from the outside (for example, the host device 2), and uses the received write data items as ECC encoder inputs to generate multiple data units independent from each other. With the FIG. 6 example followed, eight data units ECC_N to ECC_N+1 are generated in parallel, and written in parallel to sets of unit memory areas US in a single erase management unit.

More specifically, the memory controller 12 first writes data unit sections in a set of corresponding unit memory areas US of a single word line set (for example, word line set WLS0) of the semiconductor memories 11-0 to 11-7 as illustrated in FIG. 7. In the FIG. 7 example, the memory controller 12 writes, in the respective unit memory areas US of the word line set WLS0 from the semiconductor memories 11-0, 11-1, 11-2, 11-3, 11-4, 11-5, 11-6, and 11-7, corresponding parts of data units ECC_N+1, ECC_N+2, ECC_N+3, ECC_N+4, ECC_N+5, ECC_N+6, ECC_N+7, and ECC_N in parallel.

The memory controller 12 then writes, in the respective unit memory areas US of the word line set WLS1 from the semiconductor memories 11-0, 11-1, 11-2, 11-3, 11-4, 11-5, 11-6, and 11-7, corresponding parts of data units ECC_N+2, ECC_N+3, ECC_N+4, ECC_N+5, ECC_N+6, ECC_N+7, ECC_N, and ECC_N+1, in parallel as illustrated in FIG. 8. Similarly, the writes progress in units of word line sets WLS to result in the state of FIG. 6.

The memory controller 12 calculates and stores error correction codes for all the data units on RAM 16 until the parallel-written data units (for example, data units to be written in a single erase management unit EMU) finishes to be written in the semiconductor memories 11. Specifically, the memory controller 12 generates error correction codes for eight data units from ECC encoder inputs in parallel. In parallel to this generation of error correction codes, the memory controller 12 writes sections of the ECC encoder inputs already input to the formula for the error correction codes (i.e., data unit sections) in the semiconductor memory 11, for example.

The description so far is based on different columns of the unit memory areas US of the figures belonging to different semiconductor memories 11. The different columns may, however, belong to the same semiconductor memory 11. Specifically, different columns may correspond to different physical blocks MB of a single semiconductor memory 11.

As described above, according to the first embodiment, each data unit is divided into sections, and different sections are stored in respective unit memory areas US of word line sets WLS of different addresses in the different semiconductor memories 11. This avoids the whole of a particular data unit being written only in unit memory areas US of a unreliable word line layer. This makes respective error correction abilities of data units more uniform, and can avoid repeated failures of error correction of data written in unreliable areas.

### Second Embodiment

Also in the second embodiment as in the first embodiment, each data unit is divided into sections, and different sections are stored in respective unit memory areas US of word line sets WLS of different addresses in the different semiconductor memories 11. In contrast, the second embodiment is different from the first embodiment in the order of writes to the unit memory areas of the semiconductor memories 11.

FIG. 9 to FIGS. 15A and 15B illustrate the writes of the second embodiment in order along time. The memory device 1, especially the memory controller 12, of the second embodiment is configured to execute the writes described below with reference to FIG. 9 to FIGS. 15A and 15B. Each square in FIG. 9 represents a unit memory area US as in FIG. 5.

As illustrated in FIG. 9 the memory controller 12 writes the zeroth to seventh sections of the data unit ECC_N in the semiconductor memories 11-0, 11-1, 11-2, 11-3, 11-4, 11-5, 11-6, and 11-7 in unit memory areas US of word line sets WLS7, WLS6, WLS5, WLS4, WLS3, WLS2, WLS1, and WLS0 of the erase management unit EMU0 in parallel, respectively. Specifically, the memory controller 12 writes a single data unit in parallel. Such writes are contrastive to the first embodiment.

Note that the memory device 1, prior to the first write, manages the memory space of the semiconductor memory 11 as invalid data items written in unit memory areas US of word line sets WLS of addresses smaller than those of the unit memory areas US along the diagonal line in the erasure management unit EMU to which the first write will be performed. Specifically, with the FIG. 9 example followed, the memory controller 12 updates the management table for memory space as data items of some kind being already stored in the unit memory areas US of the word line set WLS0 of the semiconductor memories 11-0 to 11-6, those of the word line set WLS1 of the semiconductor memories 11-0 to 11-5, and those of the word line set WLS2 of the semiconductor memories 11-0 to 11-4 prior to the write of data unit ECC_N. These unit memory areas US may or may not have actually stored data. Further, the memory controller 12 updates the management table for the memory space as data items of some kind being already stored in the unit memory areas US of the word line set WL3 of the semiconductor memories 11-0 to 11-3, those of the word line set WLS4 of the semiconductor memories 11-0 to 11-2, those of the word line set WLS5 of the semiconductor memories 11-0 and 11-1, and that of the word line set WLS6 of the semiconductor memory 11-0.

The writes as in FIG. 9 mean parallel writes to multiple unit memory areas US lining up diagonally. The memory controller 12 writes data units in the semiconductor memories 11 in units of such diagonally-lining unit memory areas US sequentially over time.

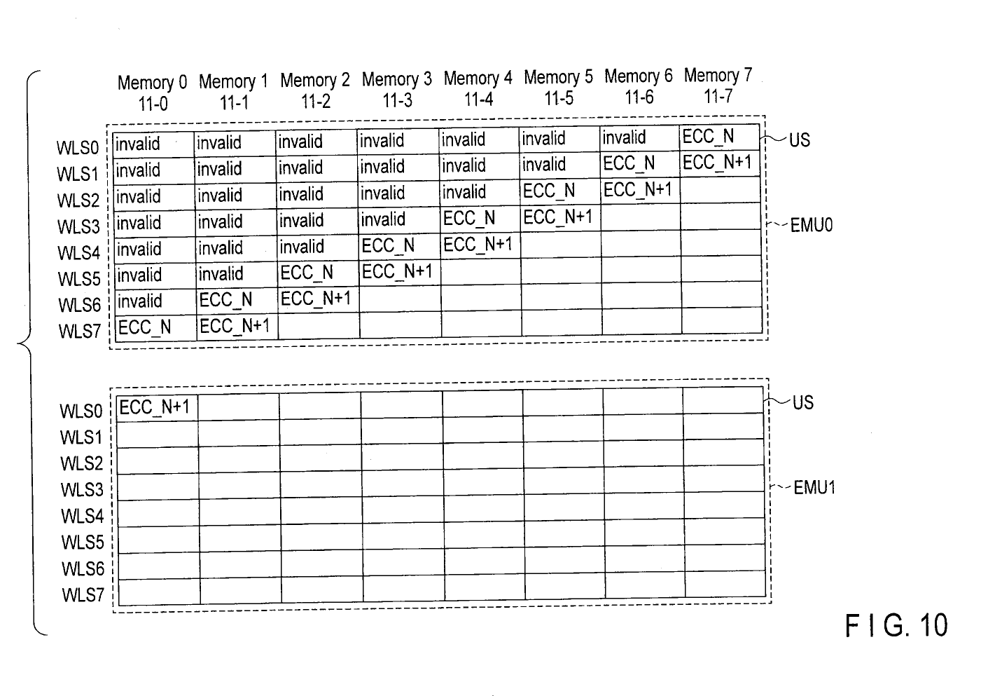

Specifically, as illustrated in FIG. 10 after FIG. 9, the memory controller 12 writes the first to seventh sections of the data unit ECC_N+1 in the semiconductor memories 11-1, 11-2, 11-3, 11-4, 11-5, 11-6, and 11-7 in respective unit memory areas US of the word line sets WLS7, WLS6, WLS5, WLS4, WLS3, WLS2, and WLS1 of the erase management unit EMU0 in parallel. The erase management unit EMU0 does not have a word line set WLS of the address subsequent to the word line set WLS7 of the unit memory area US storing the zeroth section of the data unit ECC_N. For this reason, the memory controller 12 writes the zeroth section of the data unit ECC_N+1 in a unit memory area US of the zeroth word line set WLS of a first erase management unit EMU1 in parallel to the first to seventh sections. Thus, the zeroth to the seventh sections of each data unit are written in unit memory areas US of different word line sets WLS over multiple erase management units EMU. Specifically, all sections of each data unit are distributed to be associated with different word line sets WLS. The erase management unit EMU1 may have addresses following the addresses of the erase management unit EMU0, or other addresses. As a typical example, the erase management unit EMU has an address corresponding to the number at the end of the sign EMU. The same holds true for other erase management units.

Thus, the writes progress in units of data units. For this reason, the memory controller 12 only needs to store at least one whole data unit in the RAM 16 in order to perform writes of the second embodiment. Specifically, the memory controller 12 does not need to have a RAM with a large capacity to create and store data units.

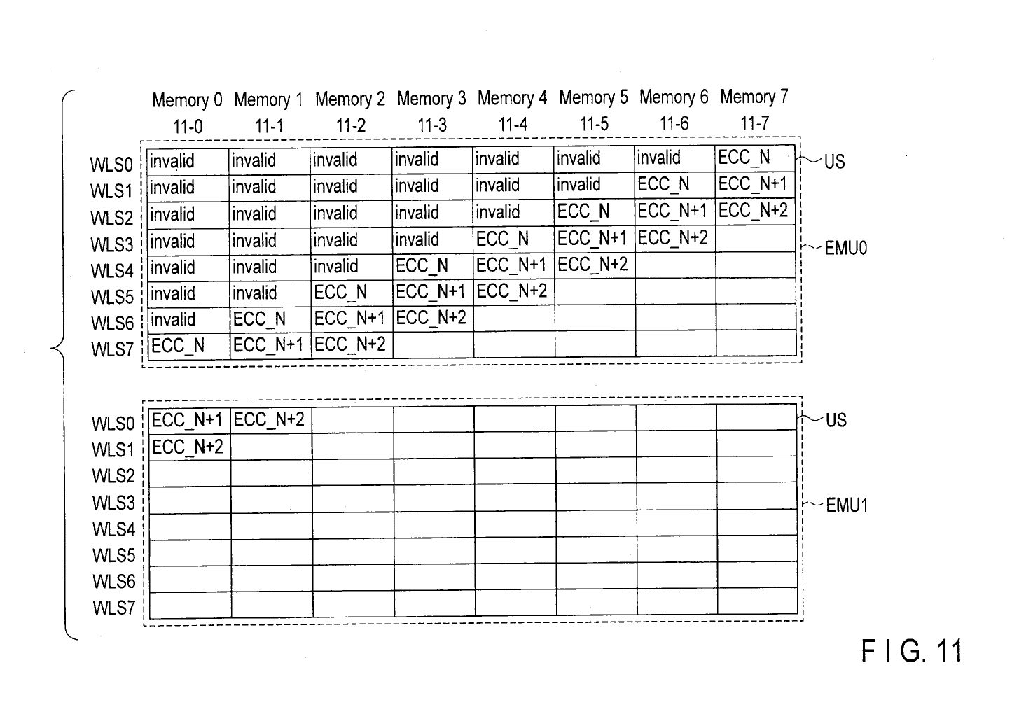

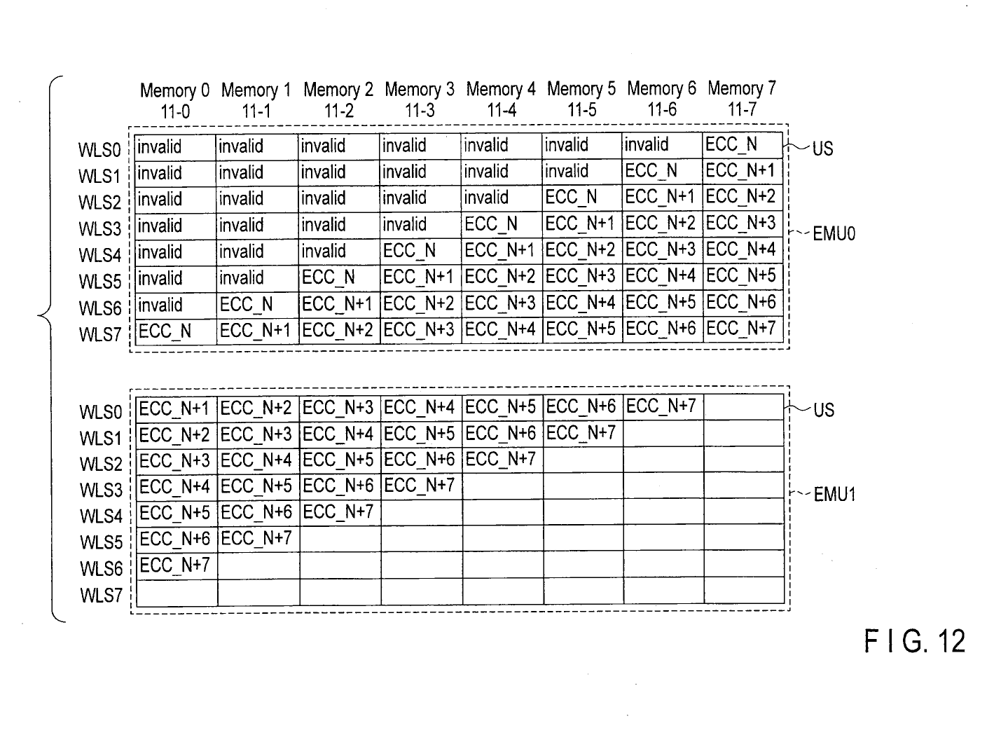

As illustrated in FIG. 11 after FIG. 10, the memory controller 12 writes the second to seventh sections of the data unit ECC_N+2 in the semiconductor memories 11-2, 11-3, 11-4, 11-5, 11-6, and 11-7 in respective unit memory areas US of the word line sets WLS7, WLS6, WLS5, WLS4, WLS3, and WLS2 of the erase management unit EMU0 in parallel. The memory controller 12 also writes the zeroth and first sections of the data unit ECC_N+2 in the semiconductor memories 11-0 and 11-1 in respective unit memory areas US of the word line sets WLS1 and WLS0 of the erase management unit EMU1 in parallel to the second to seventh sections. Similar writes are executed to result in the state of FIG. 12. FIG. 12 illustrates the state after the data units ECC_N to ECC_N+7 have been written sequentially over the erase management units EMU0 and EMU1. The writes to the erase management unit EMU0 are completed by the write of the data unit ECC_N+7.

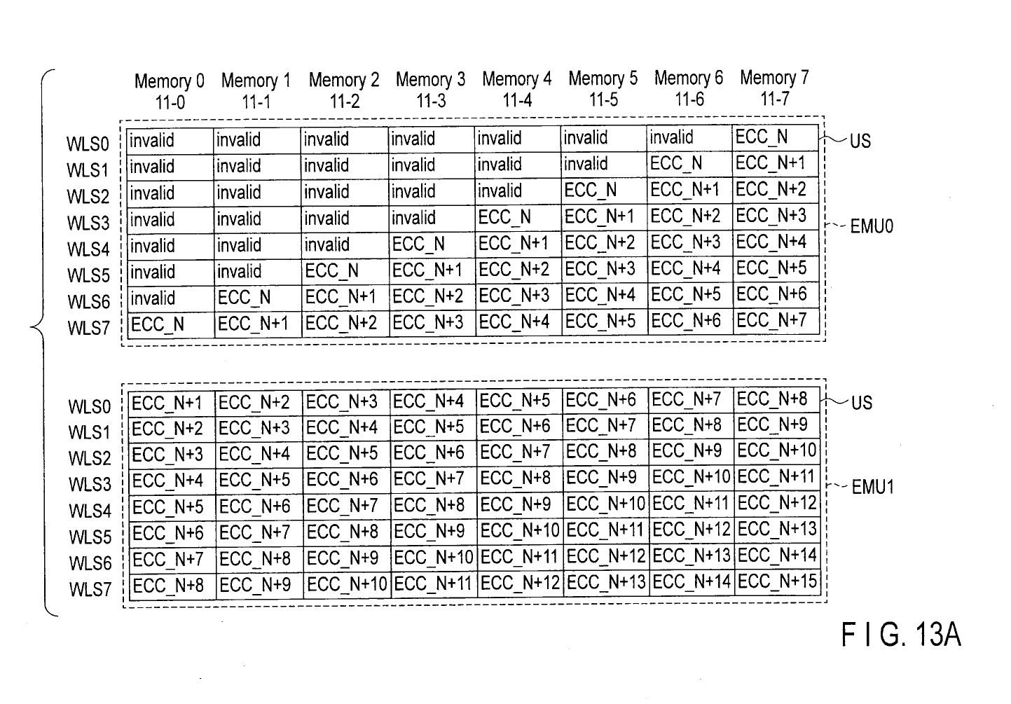

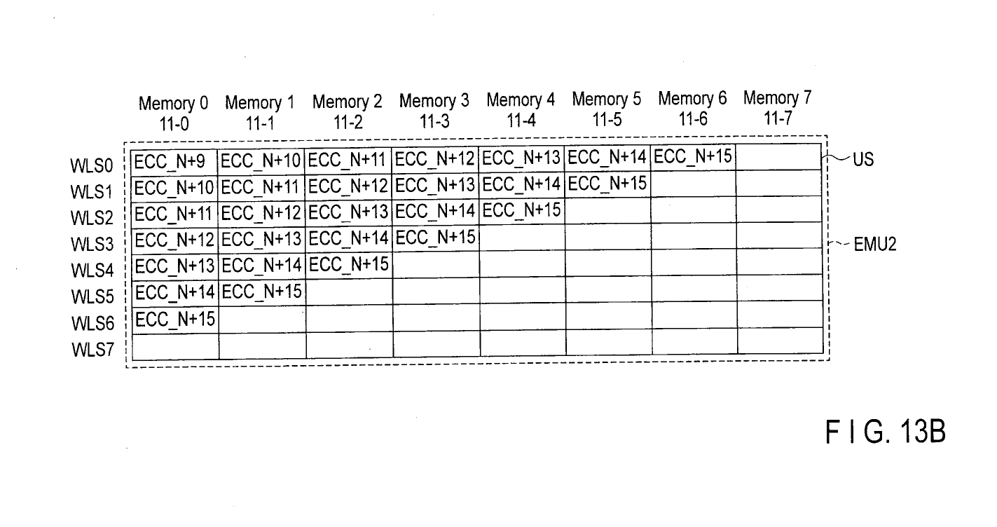

The memory controller 12 continues the writes to the semiconductor memories 11 to result in the state of FIGS. 13A and 13B following FIG. 12. FIGS. 13A and 13B illustrate the state after data units ECC_N+8 to ECC_N+15 have been written sequentially over erase management units EMU1 and EMU2. The writes to the erase management unit EMU1 are completed by the write of the data unit ECC_N+15.

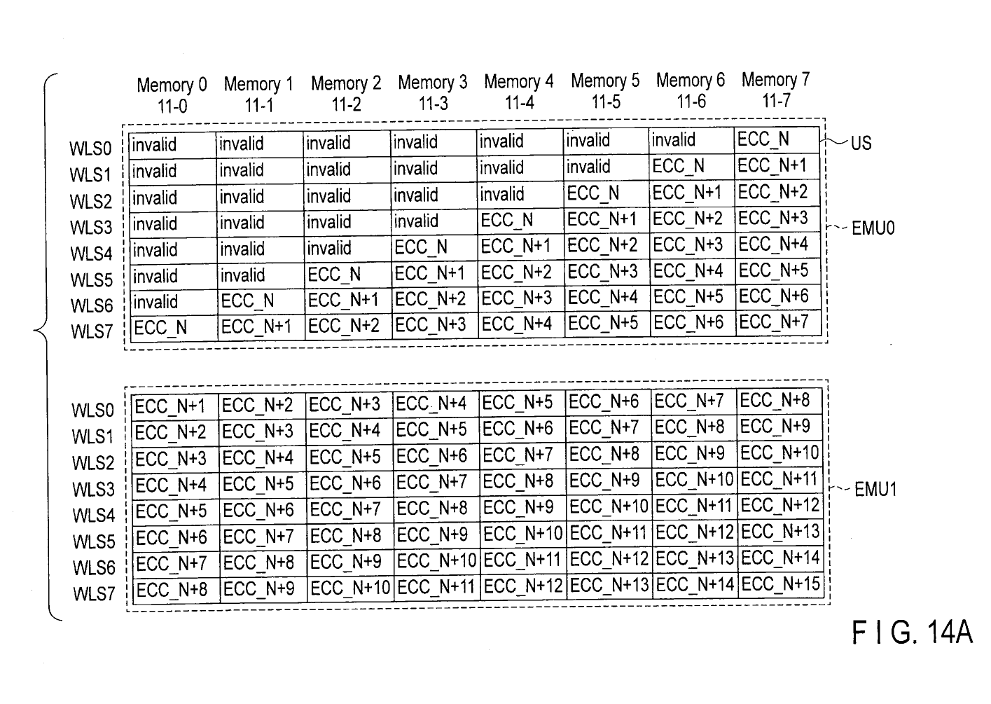

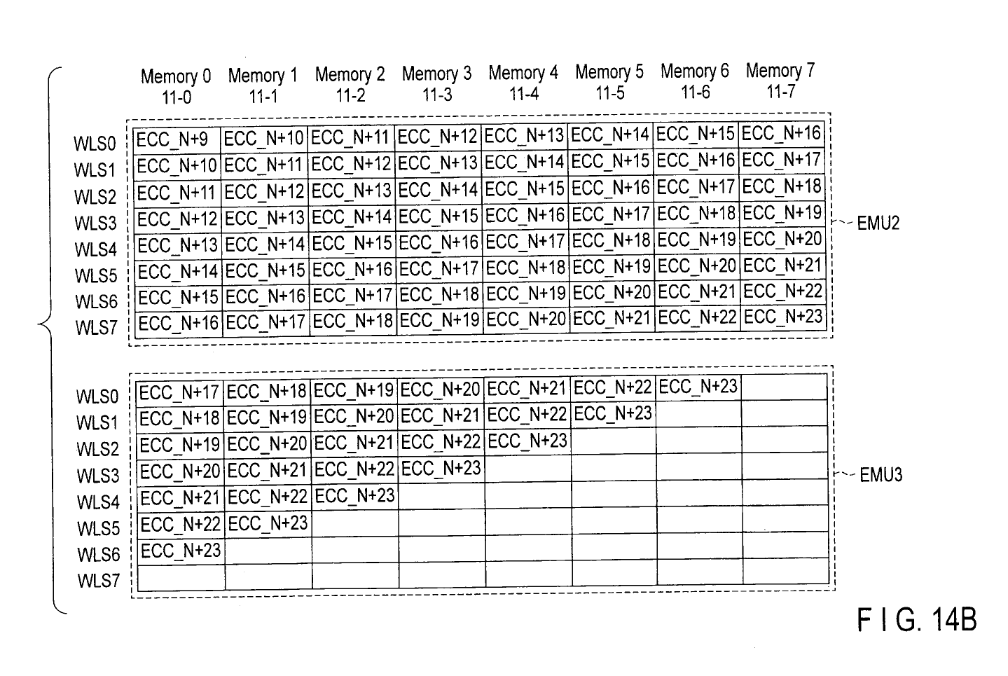

The memory controller 12 continues the writes to the semiconductor memories 11 to result in the state of FIGS. 14A and 14B following FIGS. 13A and 13B.

FIGS. 14A and 14B illustrate the state after data units ECC_N+9 to ECC_N+23 have been written sequentially over erase management units EMU2 and EMU3. The writes to the erase management unit EMU2 are completed by the write of the data unit ECC_N+23.

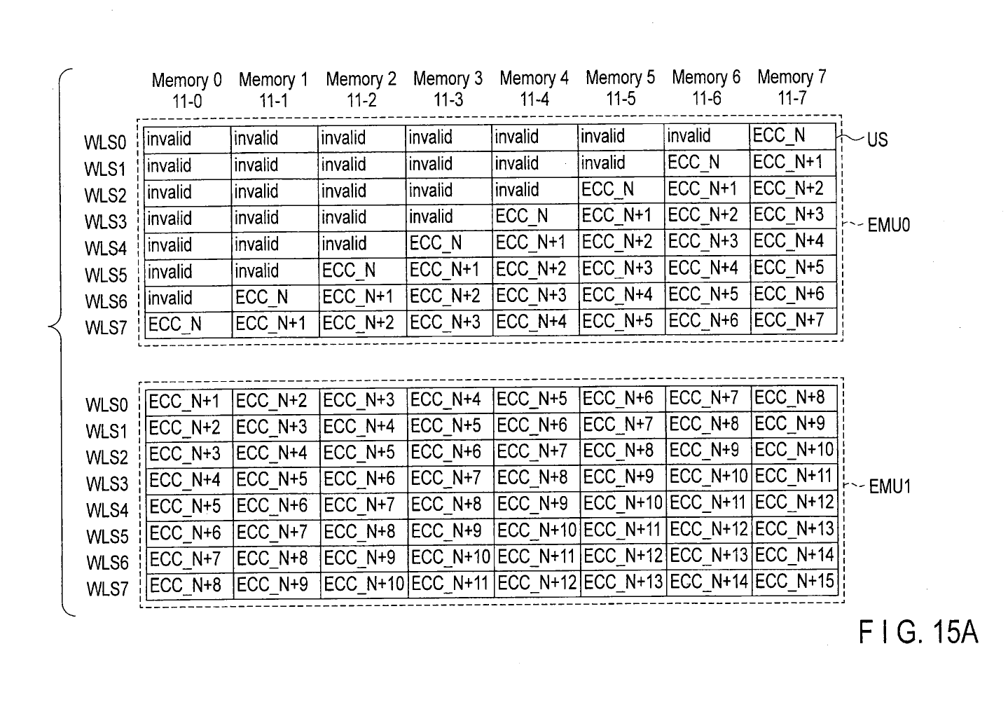

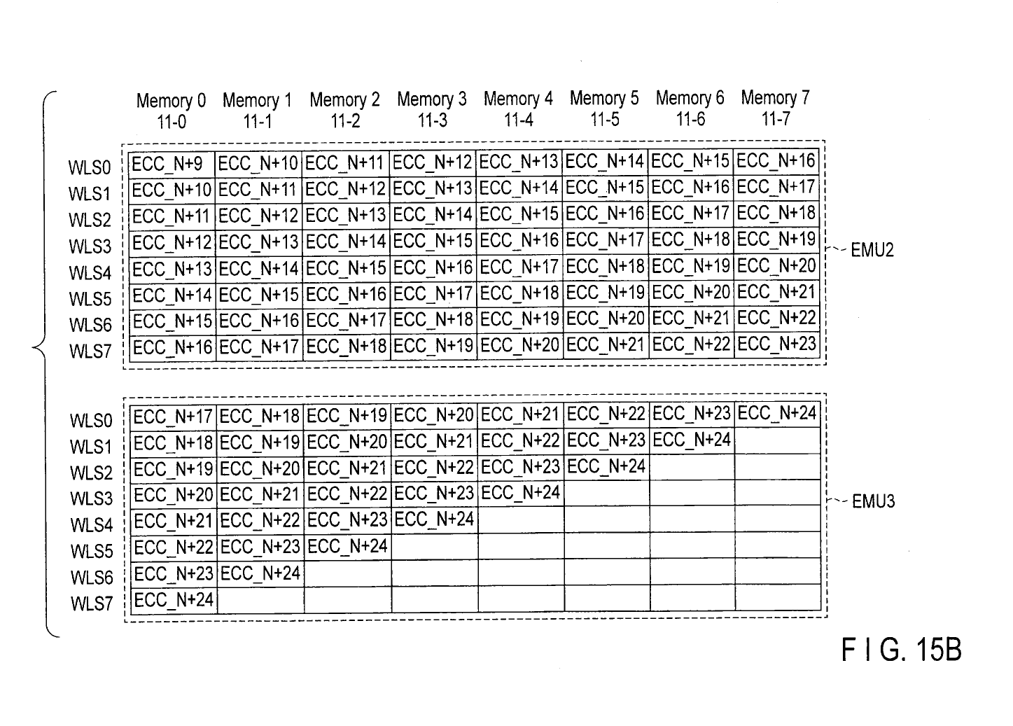

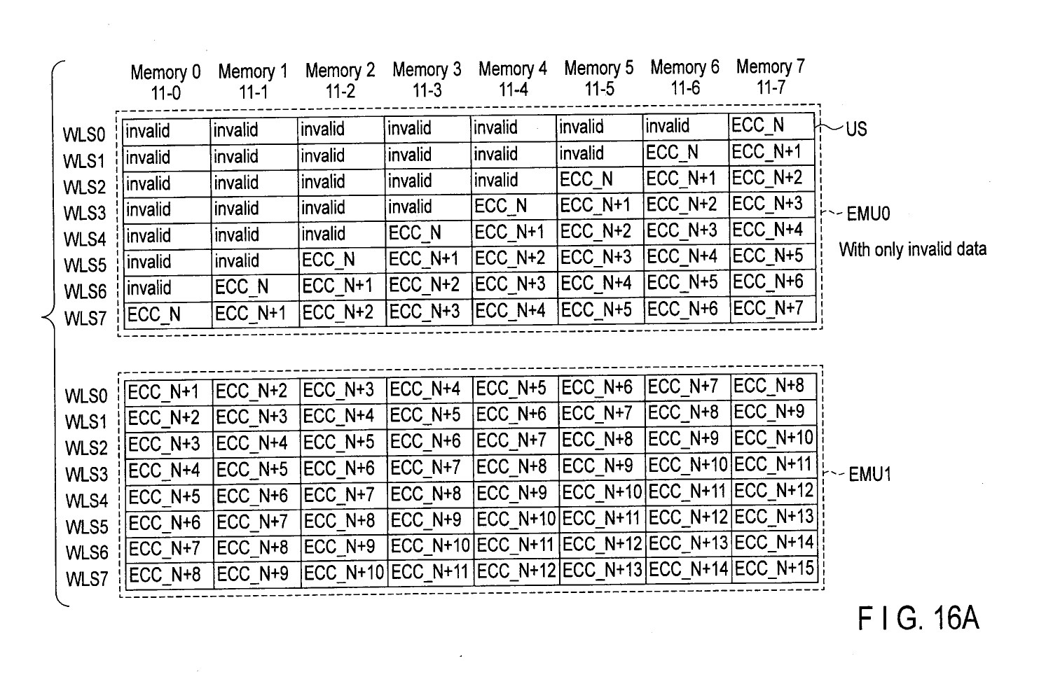

The memory controller 12 continues the writes to the semiconductor memories 11 to result in the state of FIGS. 15A and 15B following FIGS. 14A and 14B. FIGS. 15A and 15B illustrate the state after data unit ECC_N+24 has been written in an erase management unit EMU3.

As a typical example, in FIGS. 9 to FIGS. 15A and 15B, data are written in the unit memory areas US in ascending order of address from the unit memory area US of a word line set WLS of a smaller address. The writes in such an order are, however, not necessary.

FIGS. 9 to FIGS. 15A and 15B illustrate an example of a single data unit spreading over two erase management units EMU. The second embodiment is, however, not limited to this example. A single data unit can spread over three or more erase management units depending on the number of the semiconductor memories 11 (i.e., the number of columns of unit memory areas US in a single erase management unit EMU), and the number of word line sets WLS of a single semiconductor memory 11 (i.e., the number of rows of unit memory areas US in a single erase management unit EMU).

As described above, according to the second embodiment, each data unit is divided into sections, and different sections are stored in respective unit memory areas US of word line sets WLS of different addresses in the different semiconductor memories 11 as in the first embodiment. Therefore, the same advantages as in the first embodiment can be obtained. Moreover, in the second embodiment, data is written in the semiconductor memories 11 on a data-unit-to-data-unit basis, i.e., each data unit is written in parallel to unit memory areas US of word line sets WLS of different addresses of different semiconductor memories 11. This eliminates the necessity for the memory controller 12 to have a RAM with a large capacity to create and store the data units.

### Third Embodiment

The third embodiment is based on the first and second embodiments and relates to garbage collection used with the writes of the first and second embodiments.

When the memory device 1 receives a request to update data with a particular logical address assigned by the host device 2, it writes new data in a free area of a semiconductor memory 11, associates that logical address with that new data, and treats the pre-update data as invalid. After such invalid data increases in amount, the memory device 1 executes garbage collection. The garbage collection is performed to a particular area including both invalid data and valid data, and involves copying (or, moving) valid data to another area from the area with mixed data therein, and erasing all the data in the area which includes only invalid data as a result of the moving. The data which has a particular logical address and was in an area before being moved becomes invalid data. This is because the data of this logical address will be managed by the memory controller 12 as stored in an area after being moved. Thus, when all the data in a particular erase management unit EMU becomes invalid, the memory controller 12 erases all the data in that erase management unit.

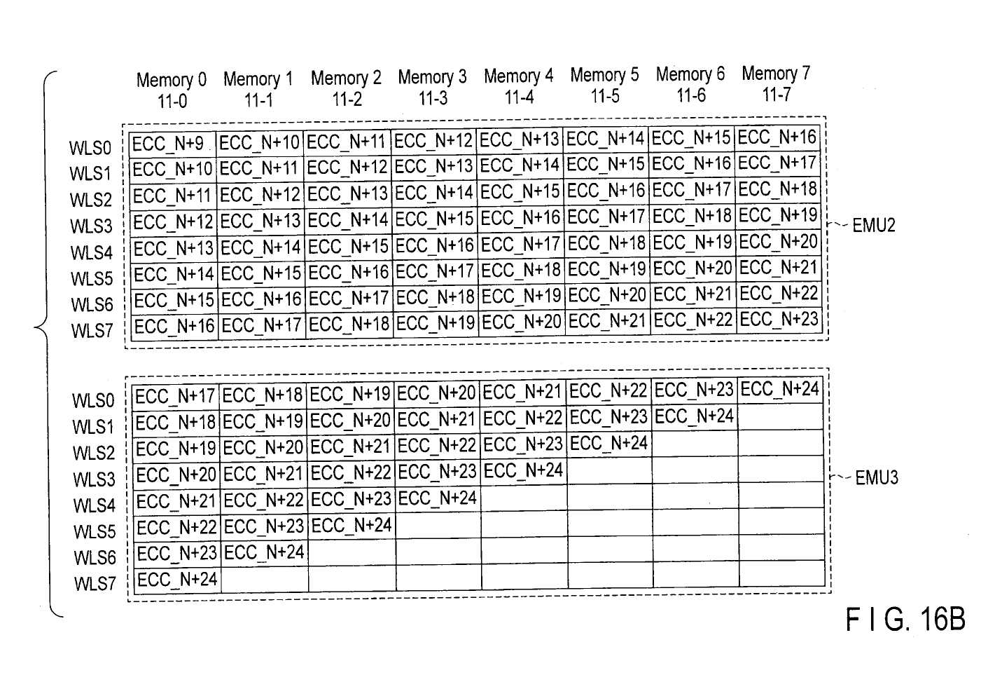

In order for errors in a particular data unit stored in the semiconductor memory 11 to be corrected, the entire data unit, i.e., all sections thereof, is necessary. Specifically, any of stored sections of a particular data unit requires all the remaining sections of that data unit in order to correct an error included therein, and they depend on each other. Therefore, even when particular data stored became invalid, the invalid data must not be erased if it is required for correcting an error. In other words, only when the entirety of a particular stored data unit becomes invalid can the memory controller 12 erase that whole data unit during the garbage collection. Specifically, in the FIG. 5 example, when all of entire data units in the erase management unit EMU0 (represented by the notation of Time N to Time N+7) become invalid, the memory controller 12 erases the data in the erase management unit EMU0. Thus, an area which requires all its data to be invalid for erasing data thereof is identical to an erase management unit EMU. The same holds true for FIG. 6 (first embodiment), and when entirety of each of the data units ECC_N-ECC_N+7 becomes invalid, the erase management unit EMU0 becomes a target for data erase. This is because, every data unit is contained within a single erase management unit EMU. In contrast, the second embodiment requires other conditions for the garbage collection. This is because a single data unit is distributed over two or more erase management units EMU as can be seen from FIG. 9, etc. Then, the third embodiment executes garbage collection to the semiconductor memories 11 in which data have been written in accordance with the second embodiment, as follows. Specifically, the memory device 1, especially the memory controller 12, of the third embodiment is configured to execute writes described below with reference to FIGS. 16A and 16B to FIGS. 20A and 20B. FIGS. 16A and 16B to FIGS. 20A and 20B each illustrate a state in example garbage collection of the third embodiment in order along time. Each square in FIGS. 16A and 16B to FIGS. 20A and 20B represents a unit memory area US as in FIG. 5.

Assume that data items are stored as in FIGS. 15A and 15B when the garbage collection is started. Assume that the memory controller 12 advances the garbage collection to result in all the data items in the erase management unit EMU0 having become invalid. The memory controller 12, however, does not erase the data items in the erase management unit EMU0 at this time. This is because the erase management unit EMU0 includes only invalid data items, but they are still necessary for error correction. That is, it is because the erase management unit EMU0 includes other sections of data units with valid sections therein (for example, the seventh section of the data unit ECC_N+7).

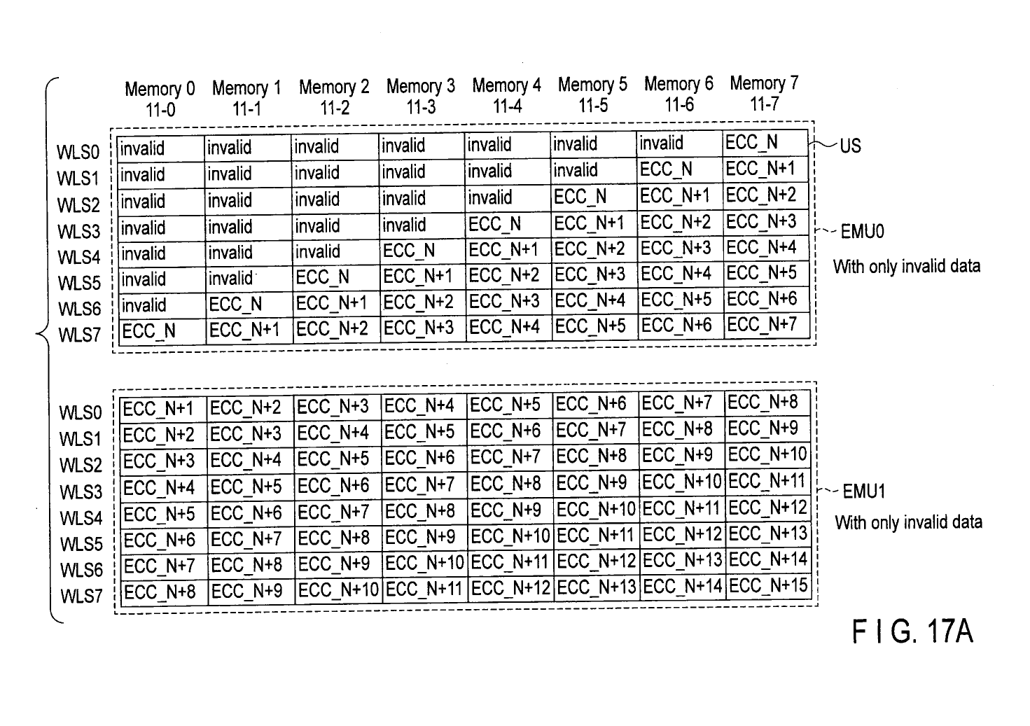

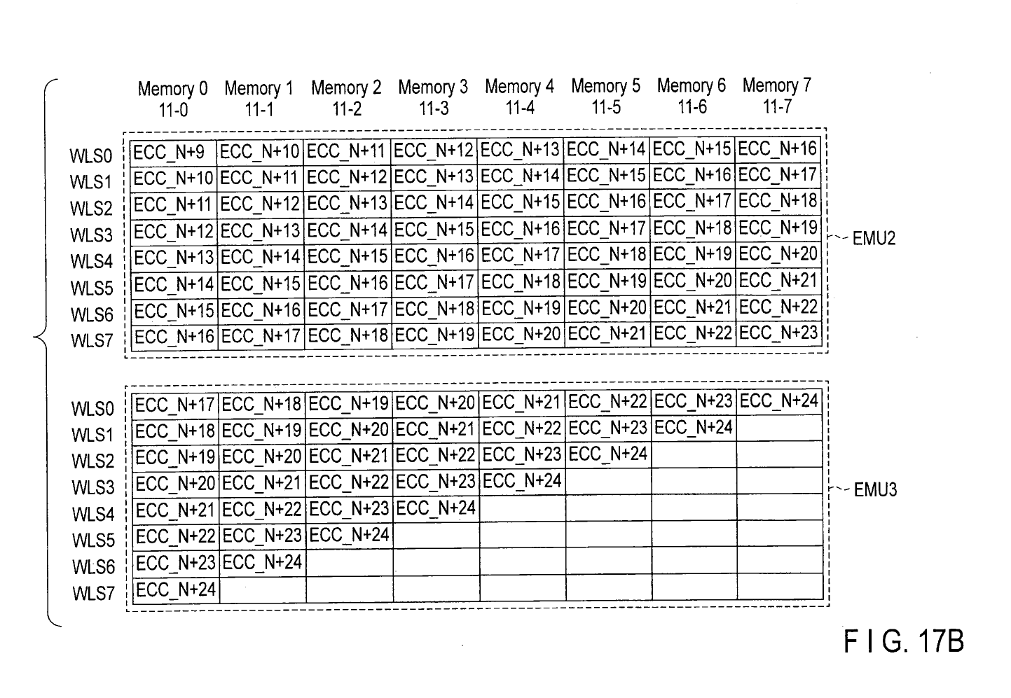

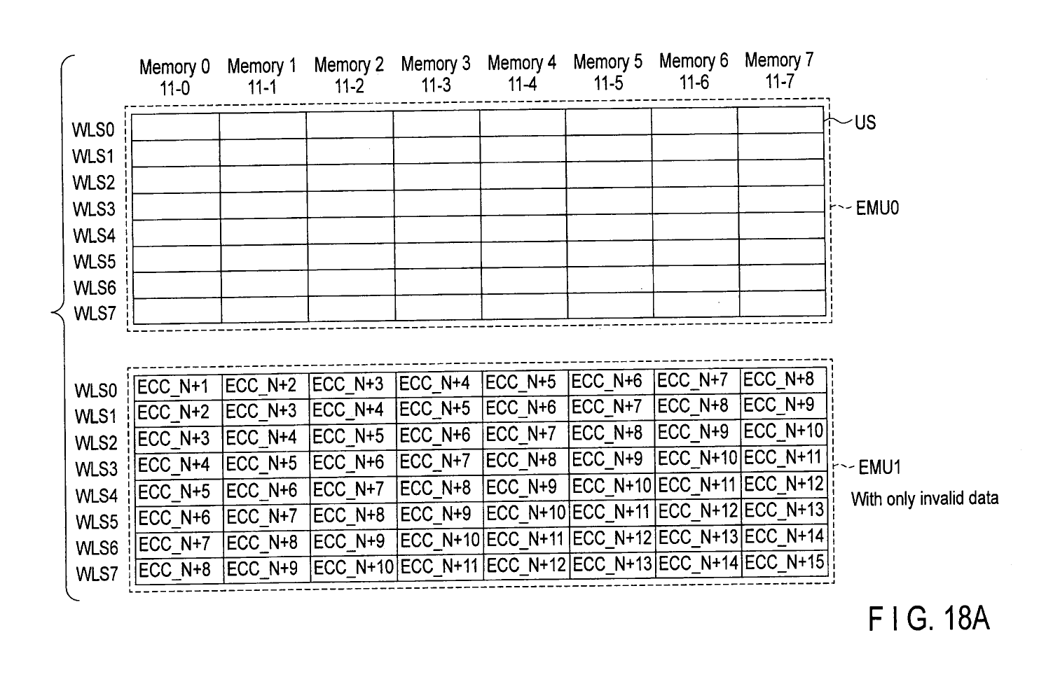

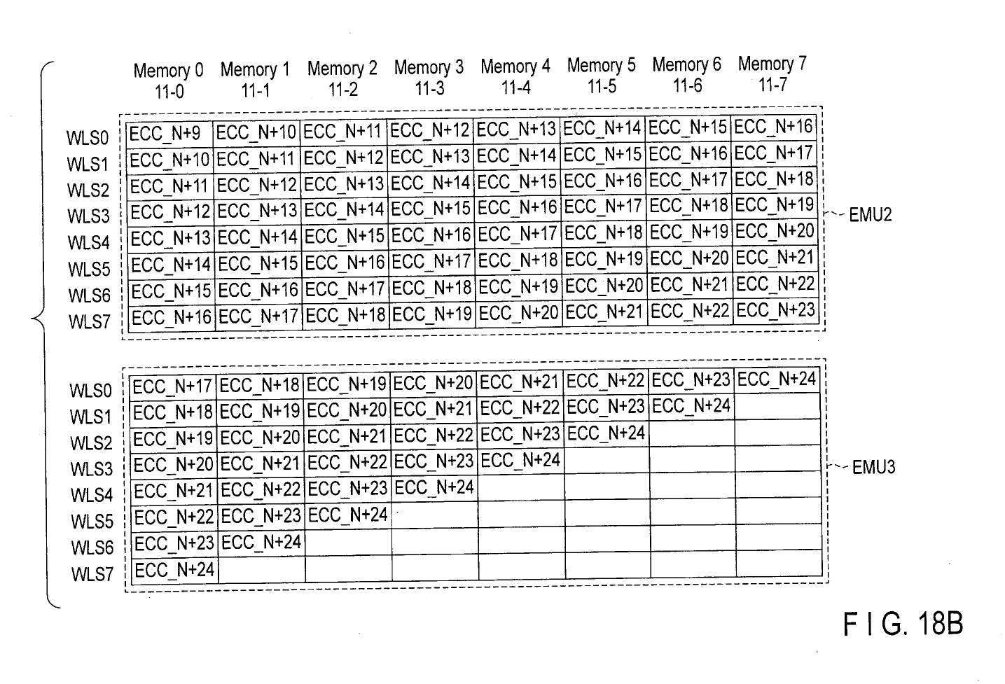

As illustrated in FIGS. 17A and 17B, the memory controller 12 advances the garbage collection to result in all the data items in the erase management unit EMU1 having become invalid in addition to the erase management unit EMU0. In accordance with this, the memory controller 12 erases all the data items in the erase management unit EMU0 as illustrated in FIGS. 18A and 18B. This is because at this time all the data items in the erase management unit EMU0 became, in addition to invalid, unnecessary for error correction. That is, when all the data items in the erase management units EMU0 and EMU1 become invalid, any of data units ECC_N-ECC_N+7, in whole or in part, which are stored in the erase management unit EMU0, become invalid. In contrast, even when all the data items in the erase management units EMU0 and EMU1 become invalid, the memory controller 12 does not erase the data items in the erase management unit EMU1. This is because the erase management unit EMU1 includes only invalid data items which are necessary for error correction. That is, it is because the erase management unit EMU1 includes other sections of data units with valid sections therein (for example, the seventh section of the data unit ECC_N+15).

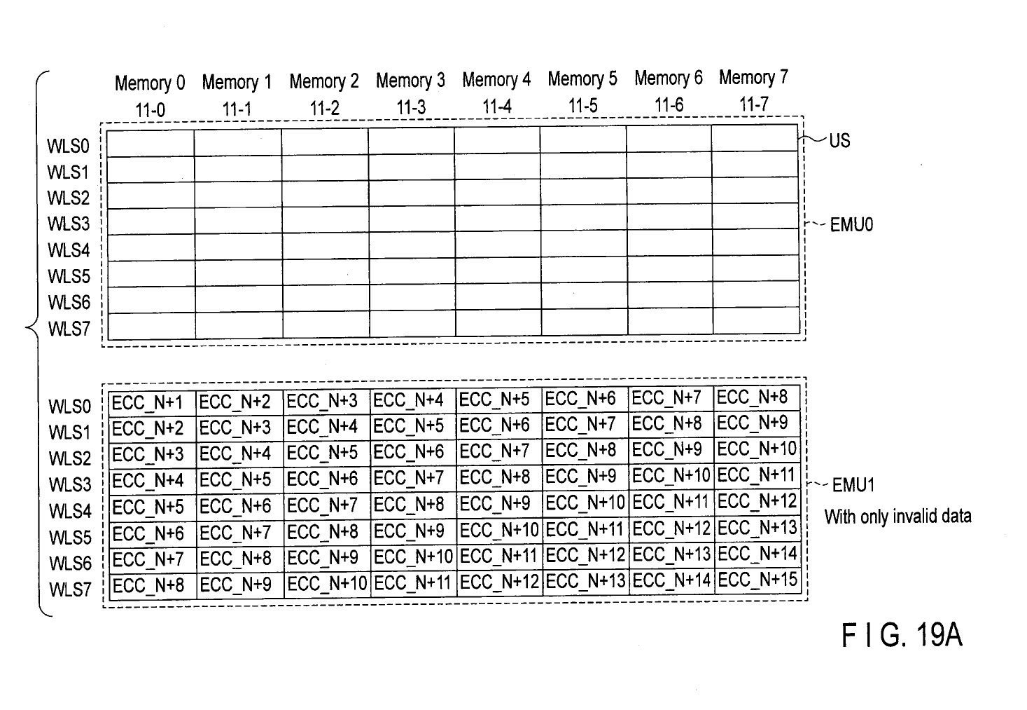

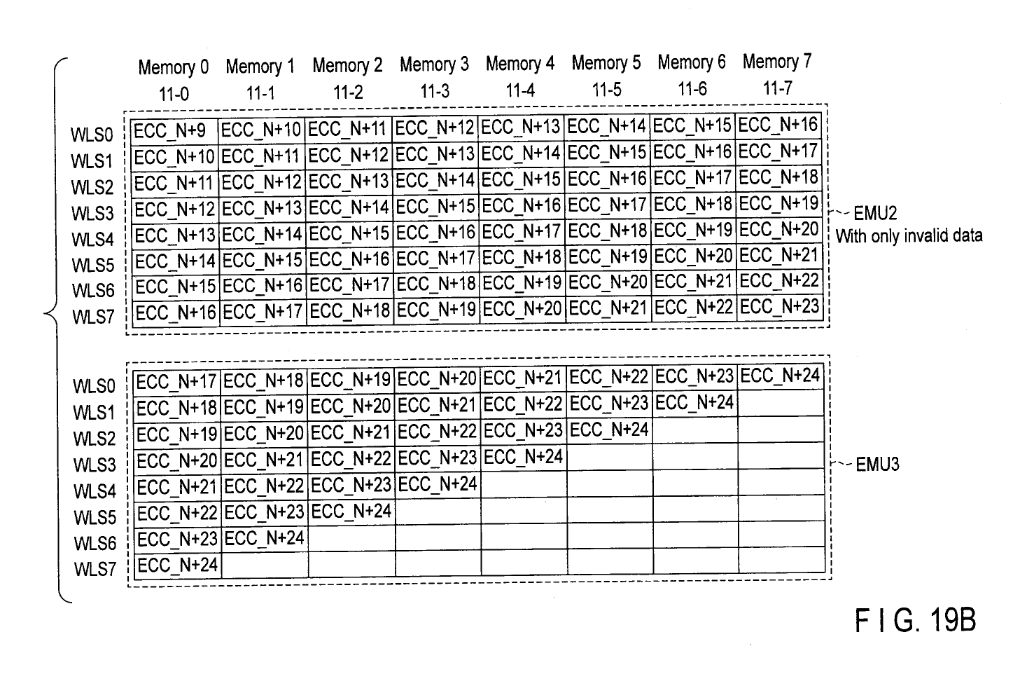

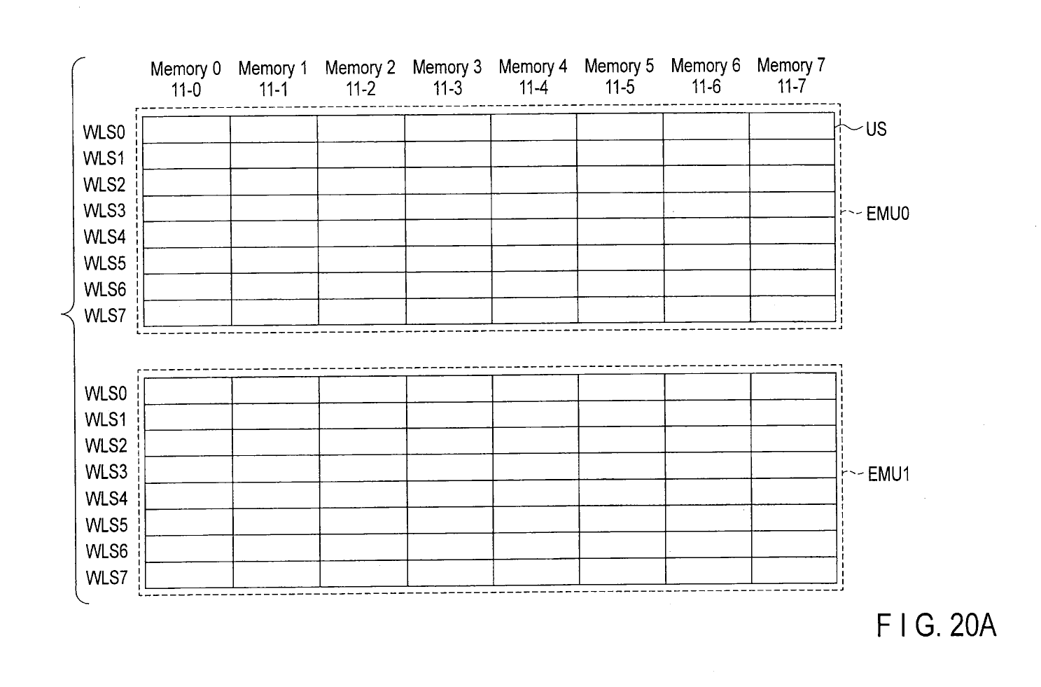

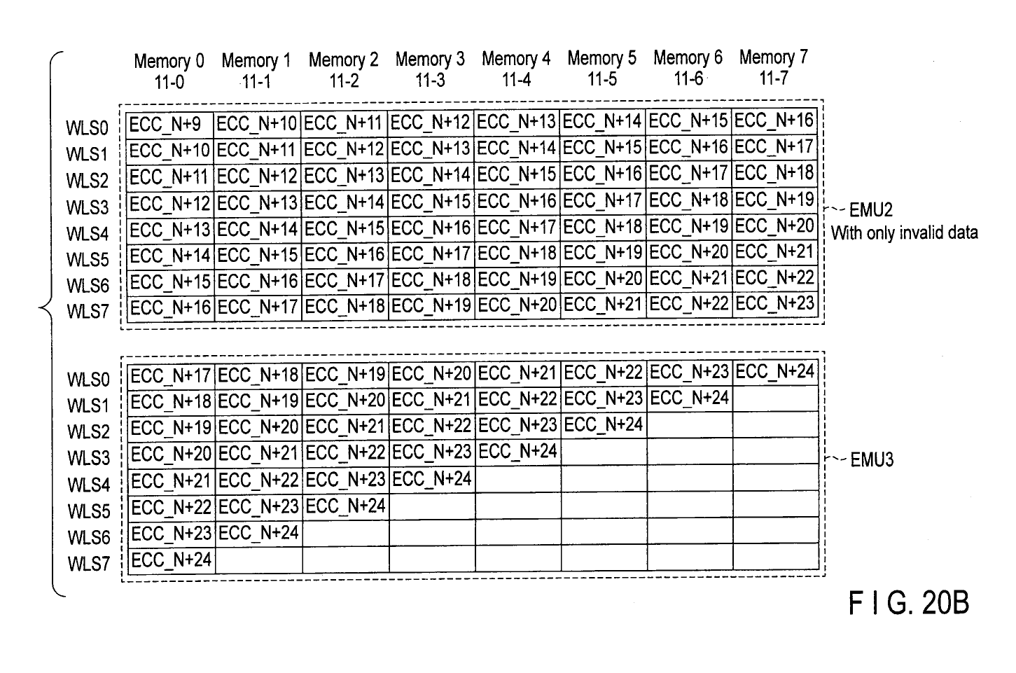

As illustrated in FIGS. 19A and 19B, the memory controller 12 advances the garbage collection to result in all the data items in the erase management unit EMU2 having become invalid in addition to the erase management unit EMU1. In accordance with this, the memory controller 12 erases all the data items in the erase management unit EMU1 as illustrated in FIGS. 20A and 20B. This is because, at this time, all the data items in the erase management unit EMU1 became, in addition to invalid, unnecessary for error correction. In contrast, even when all the data items in the erase management unit EMU2 become invalid, the memory controller 12 does not erase the data items in the erase management unit. EMU2. The invalidation of data and erasure of all data items in erase management unit EMUs are then executed based on the same principle. Specifically, for each erase management unit EMU, the memory controller 12 does not erase data items in that erase management unit EMU even when that erase management unit EMU comes to include only invalid data items. Instead, for each erase management unit EMU, the memory controller 12 erases data items in that erase management unit EMU after that erase management unit EMU comes to include only data items invalid and unnecessary for error correction.

The general description for a case of a single data unit spreading over two erase management units EMU at most is as follows. When two erase management units EMU which cooperate in storing data units become to include only invalid data items, the memory controller 12 erases the data items of one of the erase management unit set which includes only data items unnecessary for error correction. The memory controller 12 does not set one of a pair of erase management units EMU as a target for data erase when the erase management unit pair becomes to include invalid data, but when a particular erase management unit EMU comes to include only invalid and unnecessary data for error correction, the memory controller erases the data items in that erase management unit EMU.

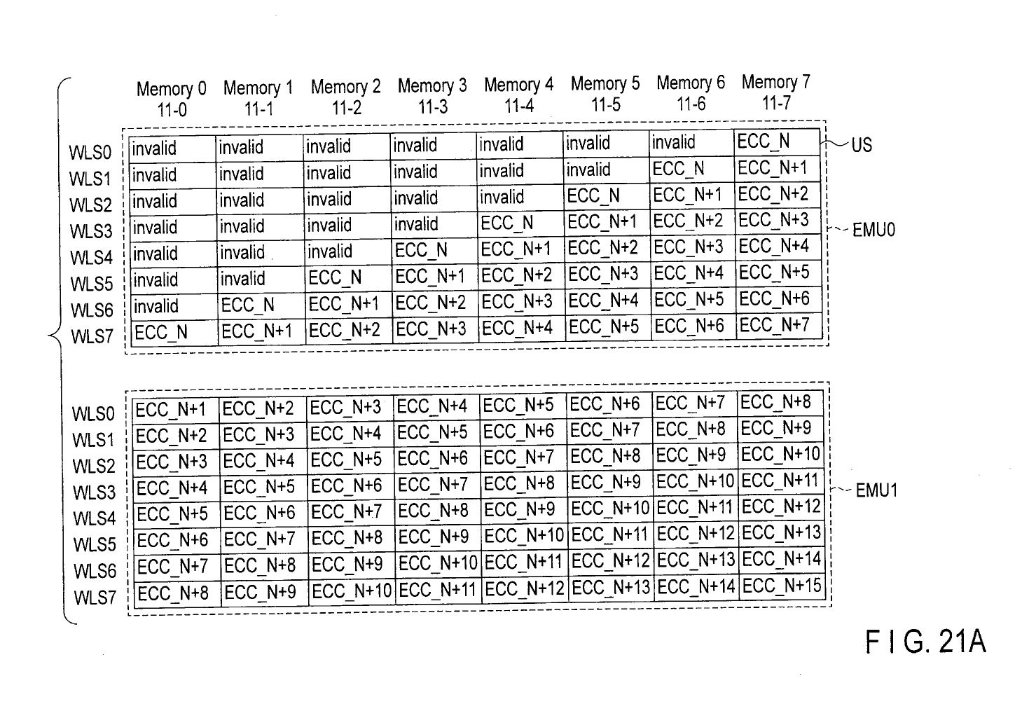

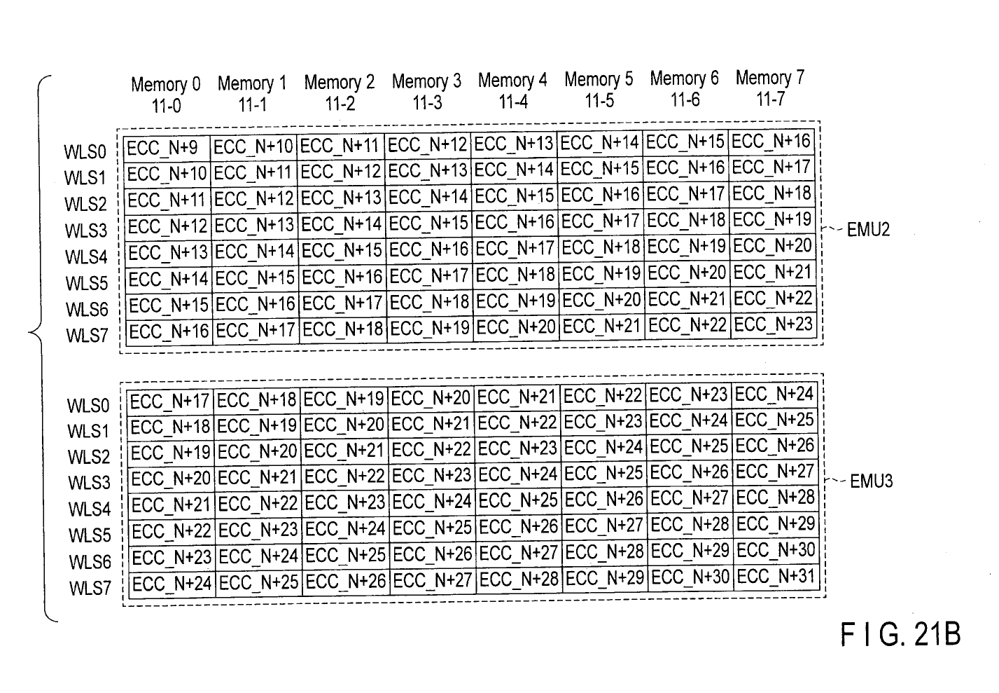

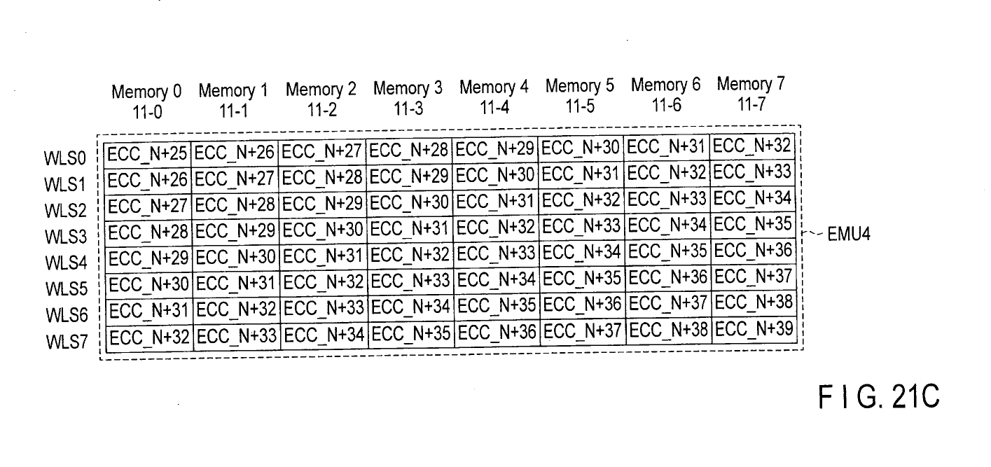

FIGS. 16A and 16B to FIGS. 20A and 20B relate to an example where stored data units become invalid generally in the order of addresses. An example with orders other than such an order will now be described with reference to FIGS. 21A, 21B and 21C to FIGS. 27A and 27B. FIGS. 21A, 21B and 21C to FIGS. 27A and 27B illustrate states in another example of garbage collection in the third embodiment sequentially along time. The memory device 1, especially the memory controller 12, of the third embodiment is configured to execute the garbage collection of FIGS. 21A, 21B, and 21C to FIGS. 27A and 27B. Each square in FIGS. 21A, 21B and 21C to FIGS. 27A and 27B represents a unit memory area US as in FIG. 5. Assume that data items are stored as in FIGS. 21A, 21B, and 21C when the garbage collection is started. Specifically, in addition to the state of FIGS. 15A and 15B, erase management units EMU3 and EMU4 already have data units ECC_N+26 to ECC_N+39 stored in accordance with the principle described in the second embodiment.

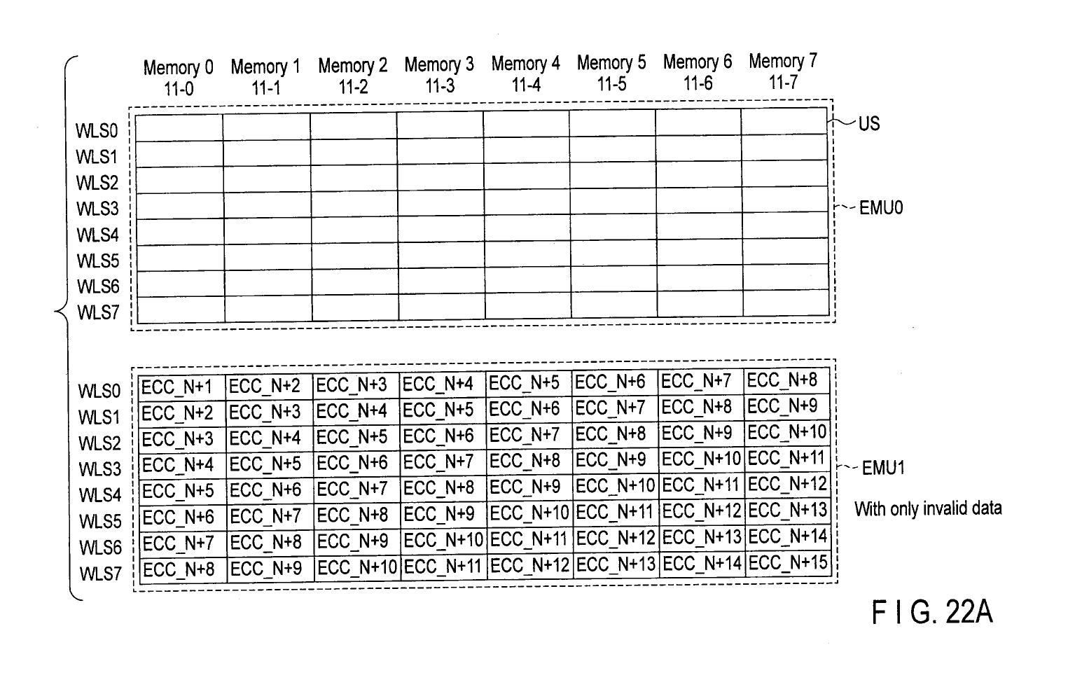

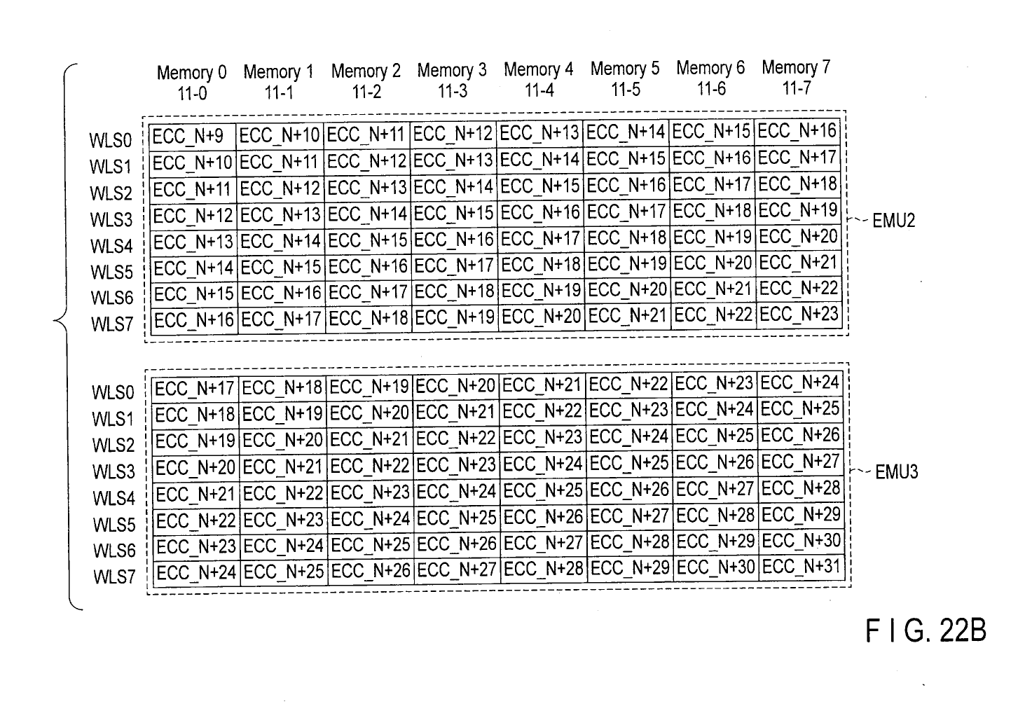

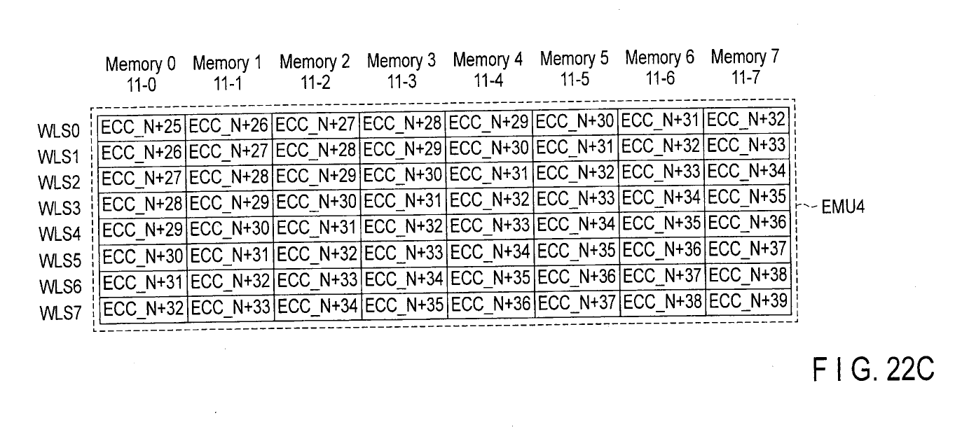

The same processes as those described with reference to FIGS. 16A and 16B to FIGS. 18A and 18B are executed up to FIGS. 22A and 22B. Specifically, the memory controller 12 advances the garbage collection to result in all the data items in the erase management units EMU0 and EMU1 having become invalid. In accordance with this, the memory controller 12 erases the data items in the erase management unit EMU0. At this time, the memory controller 12 does not erase the data items in the erase management unit EMU1.

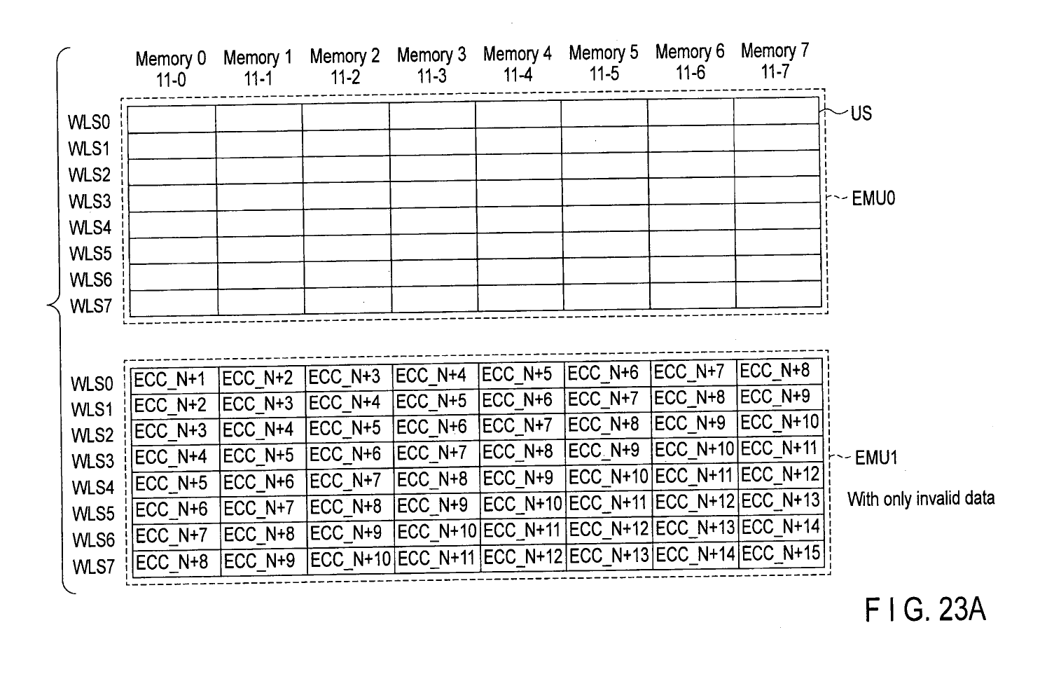

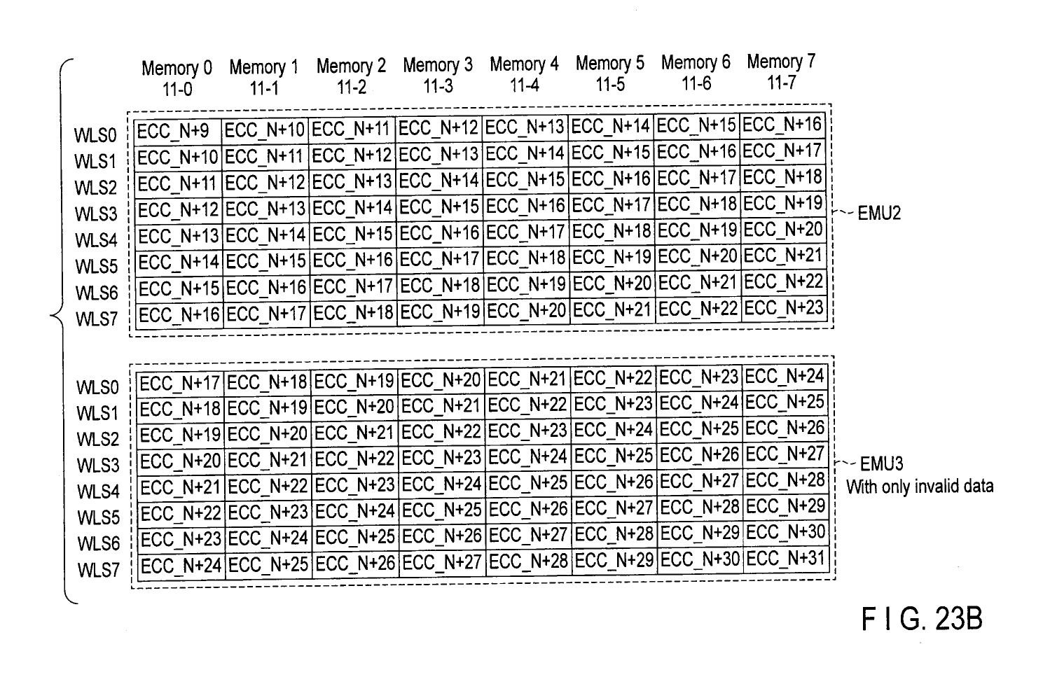

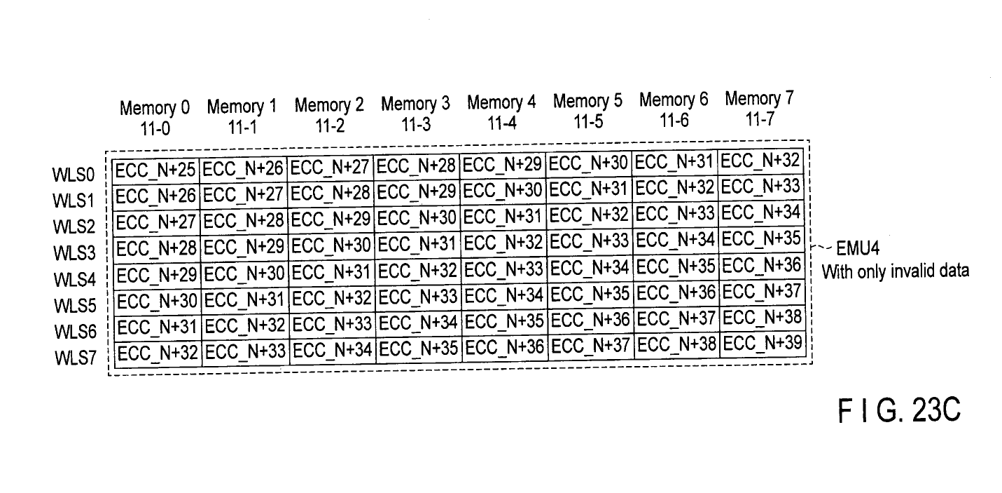

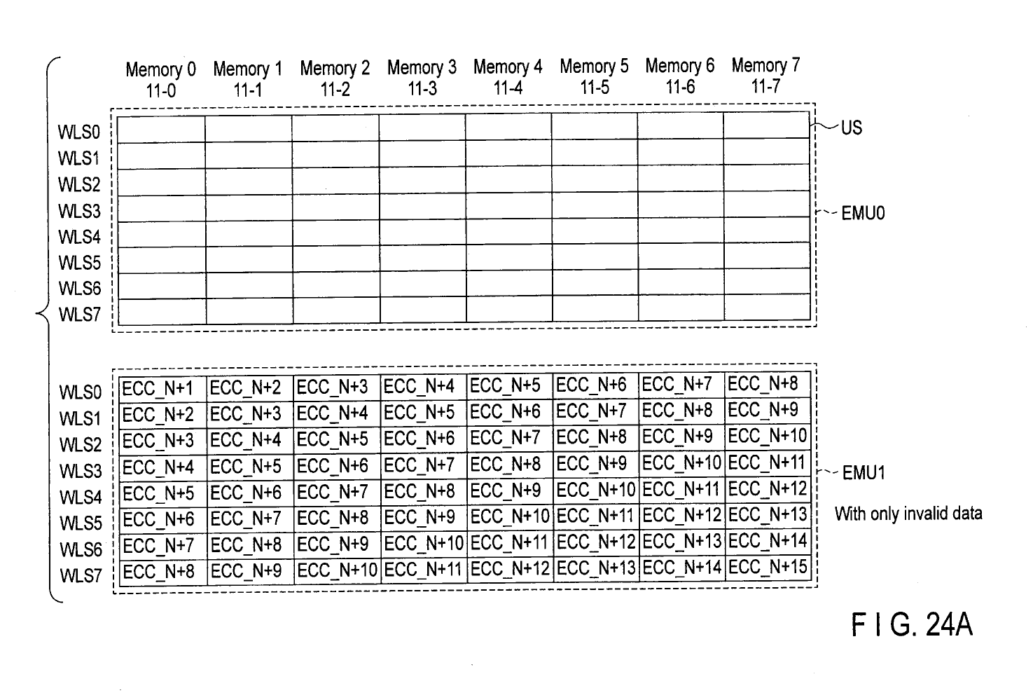

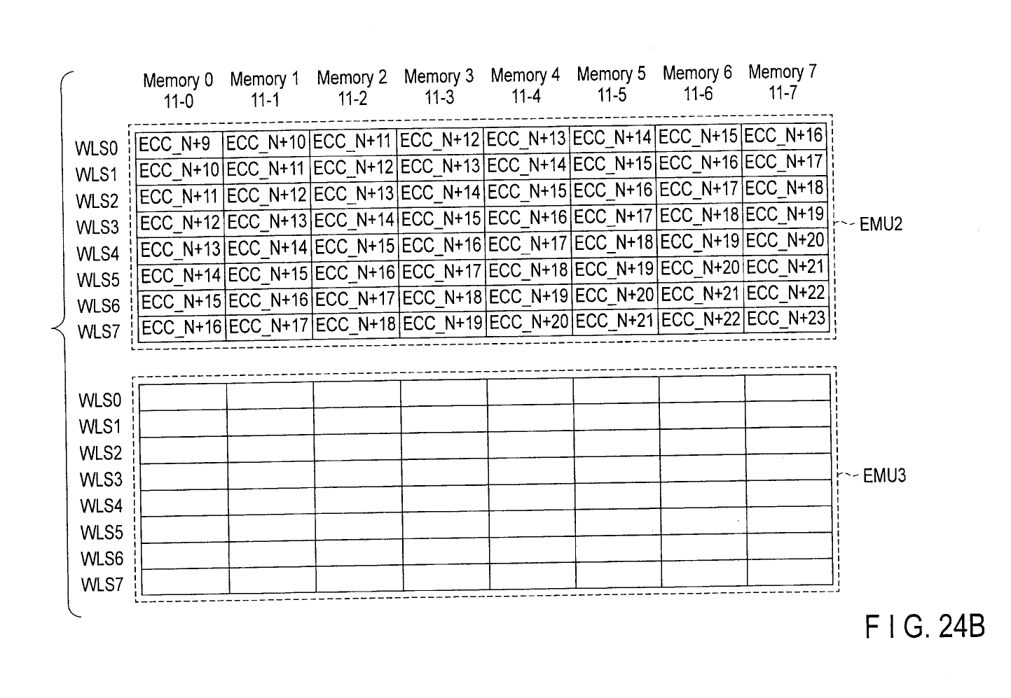

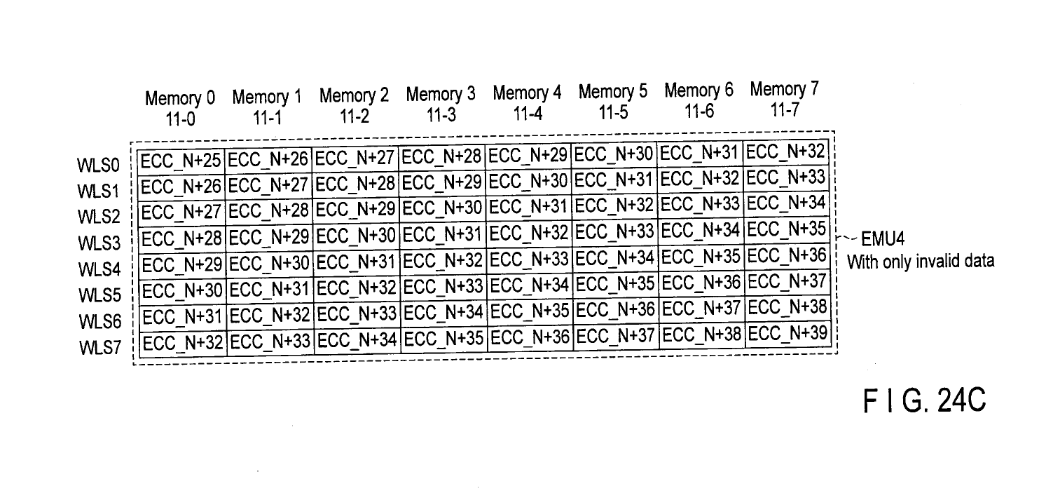

As illustrated in FIGS. 23A, 23B, and 23C, the memory controller 12 advances the garbage collection to result in all the data items in erase management units EMU3 and EMU4 having become invalid. In accordance with this, the memory controller 12 erases the data items in the erase management unit EMU3 as illustrated in FIGS. 24A, 24B, and 24C. At this time, the memory controller 12 does not erase the data items in the erase management unit EMU4.

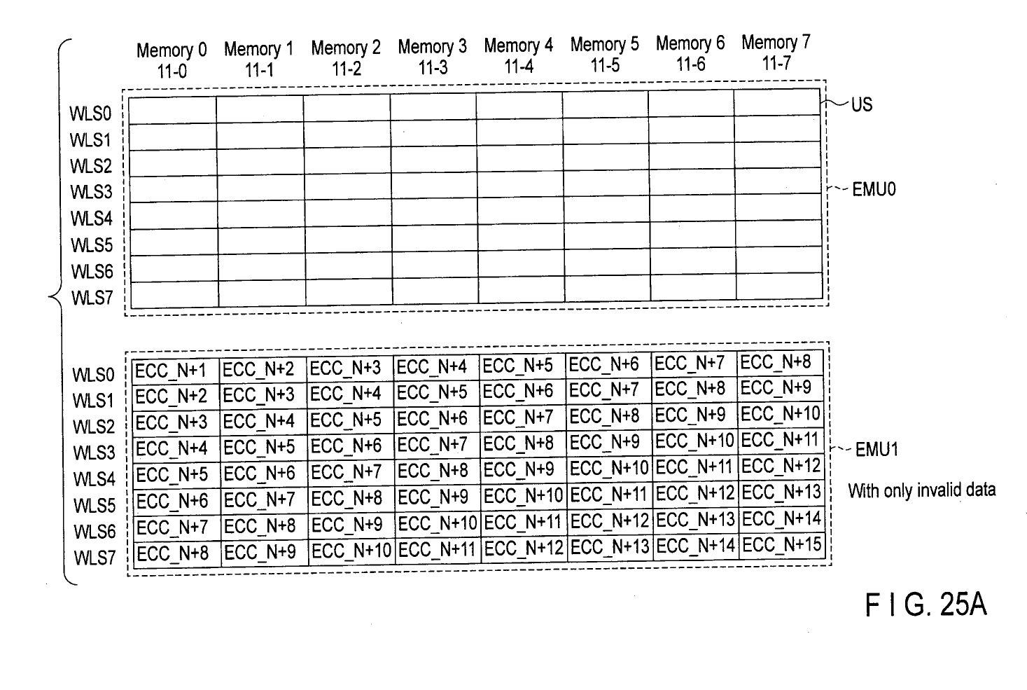

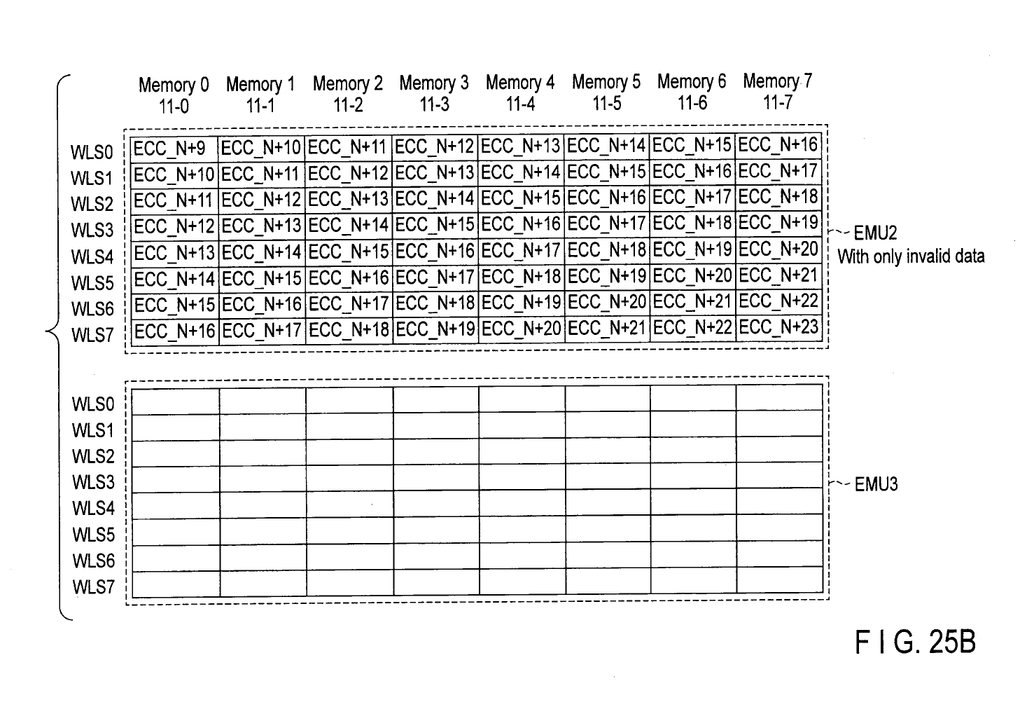

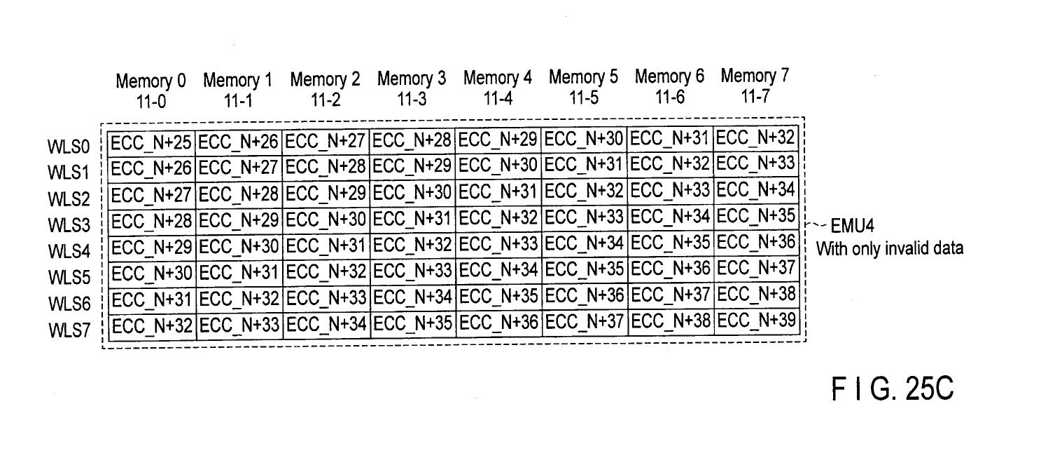

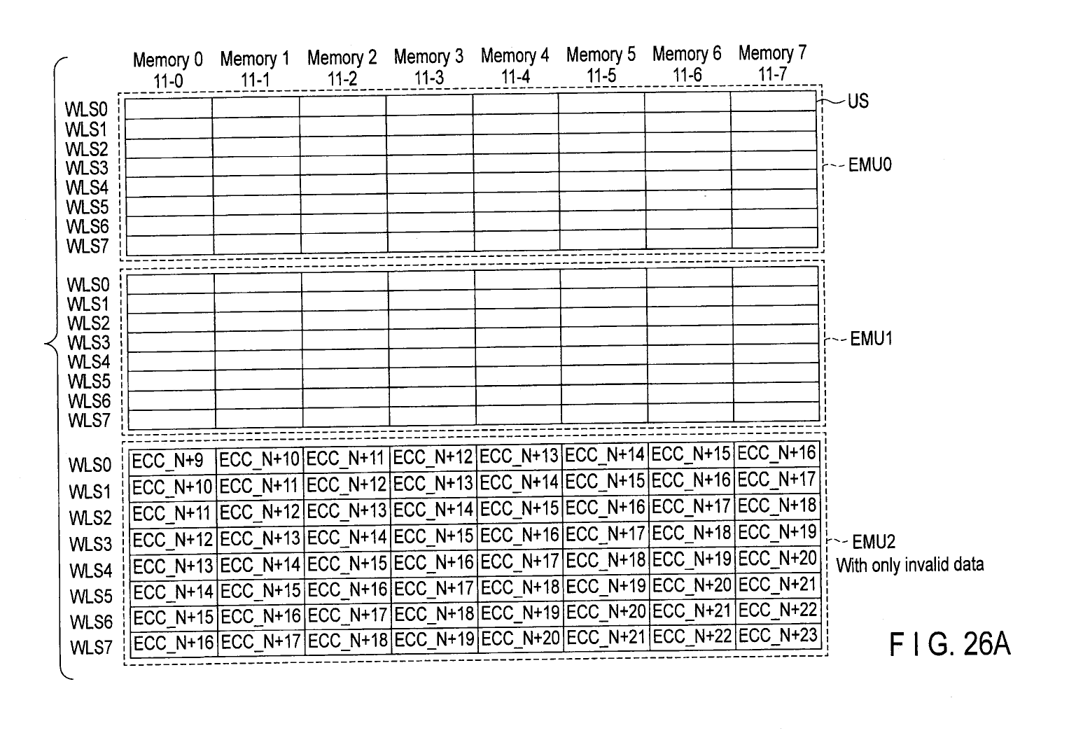

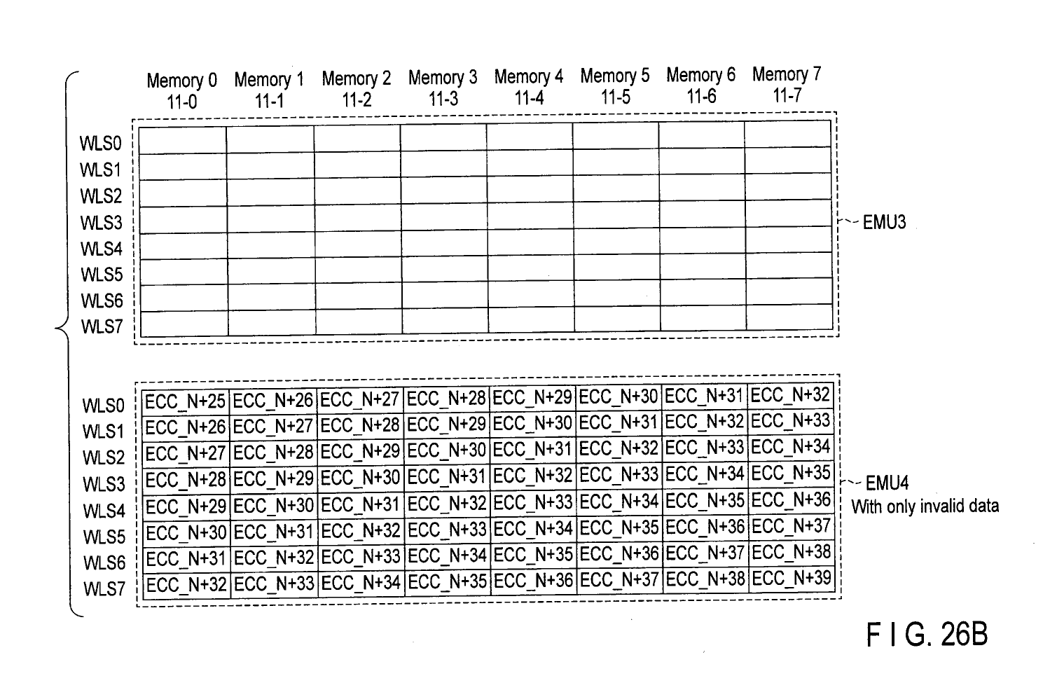

As illustrated in FIGS. 25A, 25B, and 25C, the memory controller 12 advances the garbage collection to result in all the data items in erase management unit EMU4 having become invalid. With all the data items in the erase management unit EMU2 invalid, the invalid data items in the erase management unit EMU1 are now unnecessary for error correction. In accordance with this, the memory controller 12 erases the data items in the erase management unit EMU1 as illustrated in FIGS. 26A and 26B. This is because although the erase management unit EMU1 included only invalid data items prior to FIGS. 25A, 25B, and 25C, some invalid data items were still necessary for error correction.

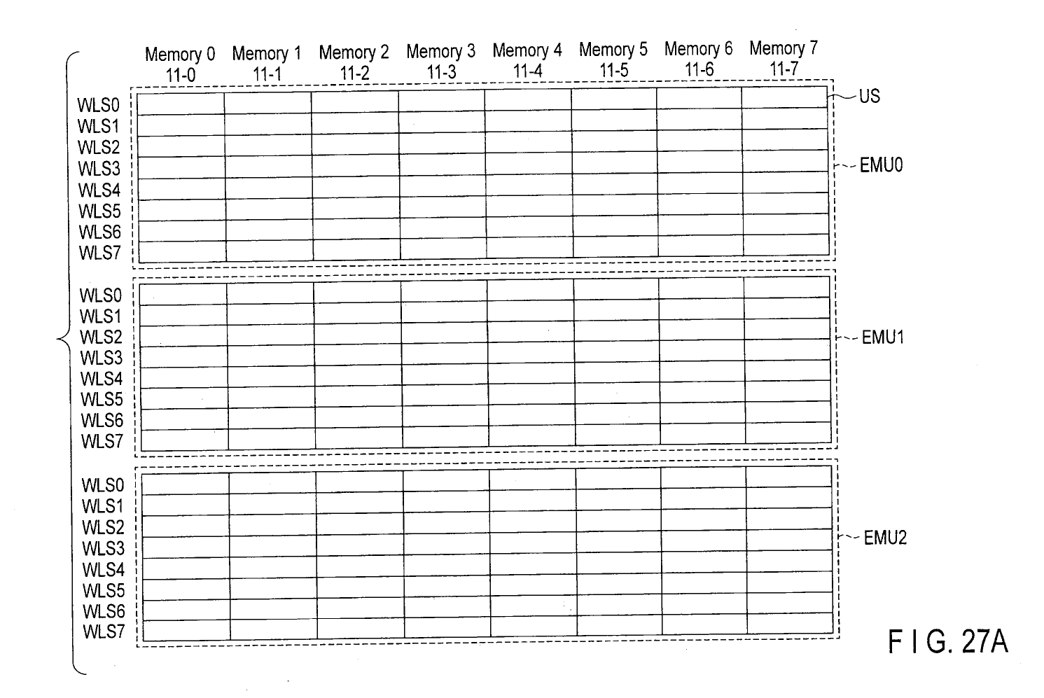

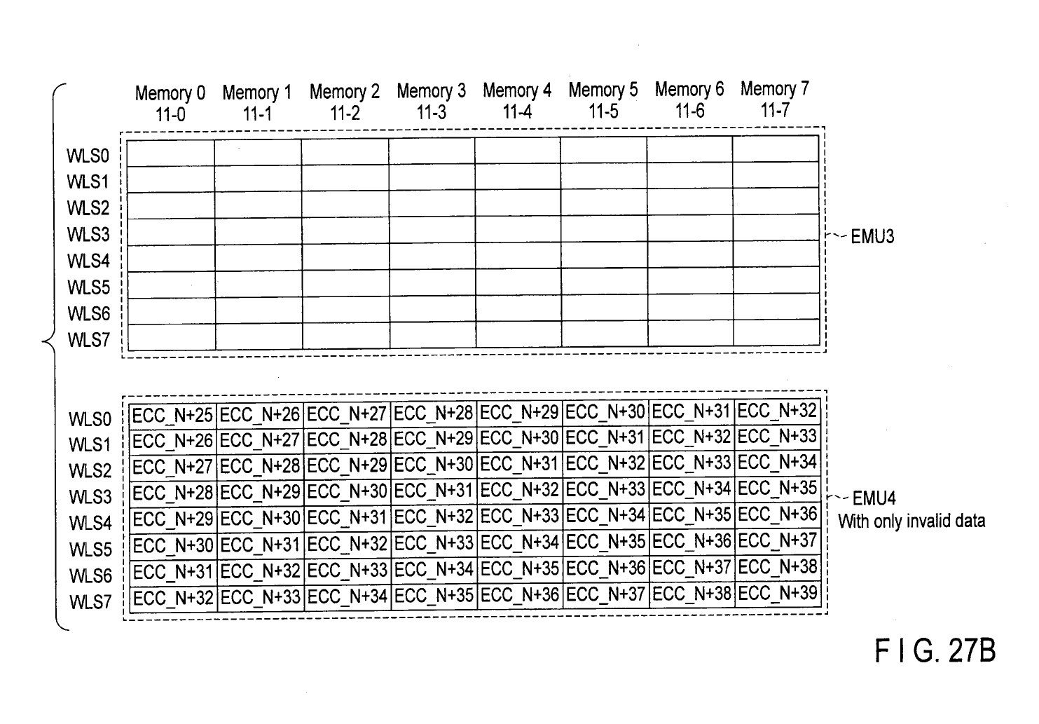

Moreover, with all the data items in the erase management unit EMU1 invalid, the memory controller 12 erases the data items in the erase management unit EMU2 as illustrated in FIGS. 27A and 27B. This is because the erase management units EMU1 and EMU3 which cooperate with the erase management unit EMU2 to store data units include no (or, valid) data, and no data items in the erase management unit EMU2 are necessary for error correction.

As described above, according to the embodiment, each data unit is divided into sections, and different sections are stored in respective unit memory areas US of word line sets WLS of different addresses in the different semiconductor memories 11 as in the first embodiment. Therefore, the same advantages as the first embodiment can be obtained. Moreover, the third embodiment is based on the second embodiment, and therefore it produces the same advantages as the second embodiment. Furthermore, according to the third embodiment, when a particular erase management unit EMU becomes to include only data items invalid and unnecessary for error correction, the memory controller 12 erases data items in that erase management unit EMU. This allows garbage collection to be executed in the memory device 1 of the second embodiment.

The embodiments are not limited to those described herein and can be variously modified at the practical stage without deviating from the gist thereof. They include embodiments of various stages, and various embodiments can be extracted from appropriate combinations of the components disclosed herein. Even if some components are omitted from all the components described herein, arrangements without such components can also be extracted as embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A controller which controls a memory, wherein
the memory comprises blocks and is configured to erase data in the blocks with each of the blocks as a minimum unit,
each of the blocks comprises unit memory areas each specified by an address,
the controller is configured to:
add a code for error correction to received data to generate a data unit;
divide the data unit into data unit sections, and
write the data unit sections in unit memory areas of respective blocks, the unit memory areas having different addresses.

2. The controller of claim 1, wherein
each of the blocks comprises word lines each having an address unique within that block,
each of the word lines specifies a physical unit comprising memory cells coupled to that word line, and
each of the unit memory areas comprises at least a physical unit.

3. The controller of claim 2, wherein
the memory has a substrate,
the physical units are formed above the substrate, and
physical units having the same address in respective blocks are located at the same height from the substrate.

4. The controller of claim 1, wherein
the controller is further configured to:
generate data units in parallel, and
write respective data unit sections of the data units in the blocks in parallel.

5. The controller of claim 1, wherein
the controller is further configured to write data unit sections of a data unit in the blocks in parallel.

6. The controller of claim 1, wherein
the controller is further configured to:
use blocks having the same address as a management unit, and
erase all data items in a management unit after that management unit becomes to include only invalid data items not included in a valid data unit.

7. A controller which controls memories, wherein
each of the memories comprises unit memory areas each specified by an address,
the controller is configured to:
add a code for error correction to received data to generate a data unit;
divide the data unit into data unit sections, and
write the data unit sections in unit memory areas of respective memories, the unit memory areas having different addresses.

8. The controller of claim 7, wherein
each of the memories comprises blocks,
each of the blocks comprises word lines each having an address unique within that block,
each of the blocks comprises word lines each having a unique address within that block,
each of the word lines specifies a physical unit comprising memory cells coupled to that word line, and
each of the unit memory areas comprises at least a physical unit.

9. The controller of claim 7, wherein
the memories have respective substrates,
the physical units are formed above a corresponding one of the substrates, and
physical units having the same address in respective memories are located at the same height from respective substrates.

10. The controller of claim 7, wherein
the controller is further configured to:
generate data units in parallel, and
write respective data unit sections of the data units in the memories in parallel.

11. The controller of claim 7, wherein
the controller is further configured to write data unit sections of a data unit in the memories in parallel.

12. The controller of claim 7, wherein
each of the memories comprises blocks and is further configured to erase data in the blocks with each of the blocks as a minimum unit,
the controller is further configured to:
use respective blocks of the memories having the same address as a management unit, and
erase all data items in a management unit after that management unit becomes to include only invalid data items not included in a valid data unit.

13. A memory system comprising:
memories each comprising unit memory areas each specified by an address; and
a controller configured to:
add a code for error correction to received data to generate a data unit;
divide the data unit into data unit sections, and
write the data unit sections in unit memory areas of respective memories, the unit memory areas having different addresses.

14. The system of claim 13, wherein
each of the memories comprises blocks,
each of the blocks comprises word lines each having an address unique within that block,
each of the blocks comprises word lines each having a unique address within that block,
each of the word lines specifies a physical unit comprising memory cells coupled to that word line, and
each of the unit memory areas comprises at least a physical unit.

15. The system of claim 14, wherein
the memories have respective substrates,
the physical units are formed above a corresponding one of the substrates, and
physical units having the same address in respective memories are located at the same height from respective substrates.

16. The system of claim 13, wherein
the controller is further configured to:
generate data units in parallel, and
write respective data unit sections of the data units in the memories in parallel.

17. The system of claim 13, wherein
the controller is further configured to write data unit sections of a data unit in the memories in parallel.

18. The system of claim 13, wherein
each of the memories comprises blocks and is further configured to erase data in the blocks with each of the blocks as a minimum unit,
the controller is further configured to:
use respective blocks of the memories having the same address as a management unit, and
erase all data items in a management unit after that management unit becomes to include only invalid data items not included in a valid data unit.
